(19) United States
(12) Patent Application Publication
(10) Pub. No.: US 2016/0322218 A1
(43) Pub. Date: Nov. 3, 2016

(54) Film Forming Method and Film Forming Apparatus

(71) Applicant: TOKYO ELECTRON LIMITED, Tokyo (JP)

(72) Inventors: Noriaki FUKIAGE, Miyagi (JP); Masahide IWASAKI, Miyagi (JP); Toyohiro KAMADA, Nirasaki City (JP); Ryosuke EBIHARA, Miyagi (JP); Masanobu IGETA, Tokyo (JP)

(21) Appl. No.: 15/140,551

(22) Filed: Apr. 28, 2016

(30) Foreign Application Priority Data
May 1, 2015 (JP) 2015-094143

(51) Int. Cl. H01L 21/02; C23C 16/46; C23C 16/36; H01J 37/32; C23C 16/455

(52) U.S. Cl. CPC H01L 21/02274; H01L 21/02211; H01L 21/0217; H01L 21/02167; H01L 21/0214; H01J 37/3222; H01J 37/32899; C23C 16/4554; C23C 16/45565; C23C 16/45551; C23C 16/36; H01J 37/32752; H01J 37/3244; C23C 16/45519; C23C 16/46; H01J 2237/327; H01J 2237/338

(57) ABSTRACT

A film forming method for forming a nitride film on a workpiece substrate accommodated within a process vessel, including: performing a first reaction of supplying a first precursor gas to the workpiece substrate accommodated within the process vessel; performing a second reaction of supplying a second precursor gas to the workpiece substrate accommodated within the process vessel; performing a modification of generating plasma of a modifying gas just above the workpiece substrate by supplying the modifying gas into the process vessel and supplying microwaves from an antenna into the process vessel, and plasma-processing, by the plasma thus generated, a surface of the workpiece substrate subjected to the first and second reactions using the first and second precursor gases.

### CROSS-REFERENCE TO RELATED APPLICATION

This application claims the benefit of Japanese Patent Application No. 2015-094143, filed on May 1, 2015, in the Japan Patent Office, the disclosure of which is incorporated herein in its entirety by reference.

### TECHNICAL FIELD

Various aspects and embodiments of the present disclosure relate to a film forming method and a film forming apparatus.

### BACKGROUND

As film forming apparatuses for forming a film on a substrate, a single-substrate-type film forming apparatus which processes a wafer one by one and a batch-type film forming apparatus which processes a plurality of wafers at a time are used. In the batch-type film forming apparatus, for example, a plurality of wafers is arranged and disposed in a vertical direction of the apparatus so that a larger amount of wafers can be processed. In addition, a semi-batch-type film forming apparatus, which realizes deposition by disposing several wafers on a circular mounting table and rotating the mounting table, is used. In the semi-batch-type film forming apparatus, a region for supplying a precursor gas and a region for generating plasma of a reaction gas are provided in different regions within a process chamber. Substrates sequentially pass through these regions, whereby films having a desired thickness are formed on the substrates.

The semi-batch-type film forming apparatus includes a mounting table, a shower head and a plasma generation part. The mounting table supports the substrates and rotates about a rotary shaft. The shower head and the plasma generation part are disposed to face the mounting table and are arranged along a circumferential direction. The shower head has a substantially fan-shaped plane shape and supplies a precursor gas to the workpiece substrates passing under the shower head. The plasma generation part supplies a reaction gas and radiates microwaves, which are supplied from a waveguide, through a substantially fan-shaped antenna, thereby generating plasma of the reaction gas. An exhaust port is formed around the shower head and the plasma generation part. Injection holes for supplying a purge gas are formed in a peripheral edge of the shower head.

In a process which makes use of the aforementioned film forming apparatus, a heat treatment is performed at a temperature of about 600 to 650 degrees C., thereby forming a film of SiN, SiCN, SiBN, SiOCN or the like. However, in a film forming technique, even higher miniaturization is required. Specifically, a highly-reproducible film forming process, which is capable of meeting the miniaturization requirements while realizing low-temperature deposition and low thermal budget and capable of producing a high-performance film, is required.

### SUMMARY

According to one embodiment of the present disclosure, a film forming method for forming a nitride film on a workpiece substrate accommodated within a process vessel includes: performing a first reaction of supplying a first precursor gas to the workpiece substrate accommodated within the process vessel; performing a second reaction of supplying a second precursor gas to the workpiece substrate accommodated within the process vessel; performing a modification of generating plasma of a modifying gas just above the workpiece substrate by supplying the modifying gas into the process vessel and supplying microwaves from an antenna into the process vessel, and plasma-processing, by the plasma thus generated, a surface of the workpiece substrate subjected to the first and second reaction steps using the first and second precursor gases.

According to another embodiment of the present disclosure, a film forming apparatus includes: a process vessel divided into a plurality of regions along a circumferential direction in which workpiece substrates are moved about an axis by a rotation of a mounting table, the mounting table being configured to hold the workpiece substrates and installed to rotate about the axis so that the workpiece substrates move around the axis; a first shower head disposed to face the mounting table and configured to supply a first precursor gas to a first region among the plurality of regions of the process vessel; a second shower head disposed to face the mounting table and configured to supply a second precursor gas to a second region adjoining the first region among the plurality of regions of the process vessel; and a plasma generation part disposed to face the mounting table and configured to generate plasma of a modifying gas just above the workpiece substrates by supplying the modifying gas to a third region among the plurality of regions of the process vessel and supplying microwaves from an antenna to the third region

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating one example of a film forming apparatus according to a first embodiment.

FIG. 2 is a top view illustrating one example of the film forming apparatus according to the first embodiment.

FIG. 3 is a plane view illustrating one example of a state in which a top portion of a process vessel is removed from the film forming apparatus illustrated in FIG. 2.

FIG. 4 is an enlarged sectional view illustrating one example of a left portion of an axis X in FIG. 1.

FIG. 5 is an enlarged sectional view illustrating one example of the left portion of the axis X in FIG. 1.

FIG. 6 is a view illustrating one example of a lower surface of a unit U.

FIG. 7 is an enlarged sectional view illustrating one example of a right portion of an axis X in FIG. 1.

FIG. 8 is a flowchart illustrating a flow of one example of a film forming process of a SiCN film implemented in the film forming apparatus according to the first embodiment.

FIG. 9 is a schematic view for explaining the flow of one example of the film forming process of the SiCN film implemented in the film forming apparatus according to the first embodiment.

FIG. 10 is a flowchart illustrating a flow of one example of a film forming process of a SiOCN film implemented in the film forming apparatus according to the first embodiment.

FIG. 11 is a schematic view for explaining the flow of one example of the film forming process of the SiOCN film implemented in the film forming apparatus according to the first embodiment.

FIG. 12 is a flowchart illustrating a flow of another example of the film forming process of the SiOCN film implemented in the film forming apparatus according to the first embodiment.

FIG. 13 is a schematic view for explaining the flow of another example of the film forming process of the SiOCN film implemented in the film forming apparatus according to the first embodiment.

FIG. 14 is a sectional view illustrating one example of a film forming apparatus according to a second embodiment.

FIG. 15 is a top view illustrating one example of the film forming apparatus according to the second embodiment.

FIG. 16 is a plane view illustrating one example of a state in which a top portion of a process vessel is removed from the film forming apparatus illustrated in FIG. 15.

FIG. 17 is a view illustrating one example of an arrangement of injection holes of a shower head provided in the film forming apparatus according to the second embodiment.

FIGS. 18A to 18D are views for explaining the relationship between the arrangement of the injection holes of the shower head and the quality of a film as formed.

FIG. 19 is a schematic sectional view illustrating a configuration of two shower heads in the film forming apparatus according to the second embodiment.

FIG. 20 is a flowchart illustrating one example of a film forming process of a SiCN film implemented in the film forming apparatus according to the second embodiment.

FIG. 21 is a schematic view for explaining the flow of one example of the film forming process of the SiCN film implemented in the film forming apparatus according to the second embodiment.

FIG. 22 is a flowchart illustrating one example of a film forming process of a SiOCN film implemented in the film forming apparatus according to the second embodiment.

FIG. 23 is a schematic view for explaining the flow of one example of the film forming process of the SiOCN film implemented in the film forming apparatus according to the second embodiment.

FIG. 24 is a view illustrating an atomic composition of a SiCN film of Example 1.

FIG. 25 is a view for explaining an etching rate of the SiCN film of Example 1.

FIG. 26 is a view for explaining the relationship between a deposition temperature of the SiCN film of Example 1 and a deposition rate thereof.

FIG. 27 is a view illustrating cleavage points of a 1,2,3-triazole-based compound.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

One embodiment of a film forming method disclosed herein is directed to a film forming method for forming a nitride film on a workpiece substrate accommodated within a process vessel. The film forming method includes performing a first reaction of supplying a first precursor gas to the workpiece substrate accommodated within the process vessel. The film forming method further includes performing a second reaction of supplying a second precursor gas to the workpiece substrate accommodated within the process vessel. The film forming method further includes performing a modification of generating plasma of a modifying gas just above the workpiece substrate by supplying the modifying gas into the process vessel and supplying microwaves from an antenna into the process vessel, and plasma-processing, by the plasma thus generated, a surface of the workpiece substrate subjected to the first and second reactions using the first and second precursor gases.

In one embodiment of the film forming method disclosed herein, the first precursor gas contains silicon and the second precursor gas contains carbon atoms and nitrogen atoms.

In one embodiment of the film forming method disclosed herein, the modification is performed once each time when the first and second reactions are repeatedly performed a predetermined number of times.

In one embodiment of the film forming method disclosed herein, the film forming method further includes performing a third reaction of supplying a third gas to the workpiece substrate accommodated within the process vessel. The film forming method further includes performing a removal of purging a mechanism for supplying the first precursor gas, the second precursor gas and the third gas, the removal being performed after the first reaction, the second reaction and the third reaction but before the modification.

In one embodiment of the film forming method disclosed herein, the third gas contains oxygen atoms.

In one embodiment of the film forming method disclosed herein, the first precursor gas contains one of monochlorosilane, dichlorosilane, trichlorosilane, tetrachlorosilane and hexachlorodisilane.

In one embodiment of the film forming method disclosed herein, the second precursor gas is supplied into the process vessel together with ammonia.

In one embodiment of the film forming method disclosed herein, the second precursor gas is pyrolyzed at a temperature of 200 degrees C. or more and 550 degrees C. or less.

In one embodiment of the film forming method disclosed herein, the modifying gas is a mixed gas of NH₃ and H₂.

A film forming apparatus according to one embodiment disclosed herein includes a process vessel divided into a plurality of regions along a circumferential direction in which workpiece substrates are moved about an axis by the rotation of a mounting table configured to hold the workpiece substrates and installed to rotate about the axis so that the workpiece substrates can move around the axis. The film forming apparatus further includes a first shower head disposed to face the mounting table and configured to supply a first precursor gas to a first region among the plurality of regions of the process vessel. The film forming apparatus further includes a second shower head disposed to face the mounting table and configured to supply a second precursor gas to a second region adjoining the first region among the plurality of regions of the process vessel. The film forming apparatus further includes a plasma generation part disposed to face the mounting table and configured to generate plasma of a modifying gas just above the workpiece substrates by supplying the modifying gas to a third region among the plurality of regions of the process vessel and supplying microwaves from an antenna to the third region.

In one embodiment of the film forming apparatus disclosed herein, the first shower head is smaller in size than the second shower head.

In one embodiment of the film forming apparatus disclosed herein, the film forming apparatus further includes a gas supply/exhaust mechanism configured to prevent entry of plasma into a space between the first and second shower heads by supplying a purge gas between the first and second shower heads and around the first and second shower heads.

In one embodiment of the film forming apparatus disclosed herein, the first shower head is configured to supply the first precursor gas containing silicon and the second shower head is configured to supply the second precursor gas containing carbon atoms and nitrogen atoms.

In one embodiment of the film forming apparatus disclosed herein, the plasma generation part includes a first gas supply part configured to supply an oxygen gas to the third region and a second gas supply part configured to, after supplying the oxygen gas, supply a purge gas in order to remove the oxygen gas.

In one embodiment of the film forming apparatus disclosed herein, each of the first and second shower heads is divided into a plurality of regions, in which flow rates of an injected gas are independently controlled, radially outward from the axis of the process vessel by straight lines or curved lines extending along the circumferential direction of the process vessel. Furthermore, an inclination angle of the straight lines or the curved lines of the first shower head with respect to a radial direction of the process vessel is larger than an inclination angle of the straight lines or the curved lines of the second shower head with respect to the radial direction of the process vessel.

### First Embodiment

### One Example of a Configuration of Film Forming Apparatus 10

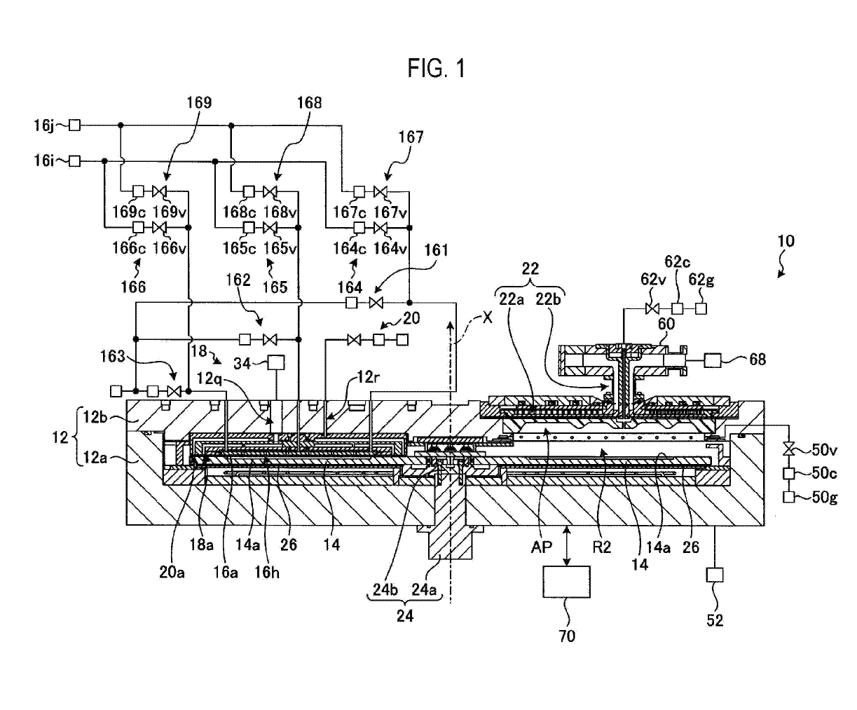

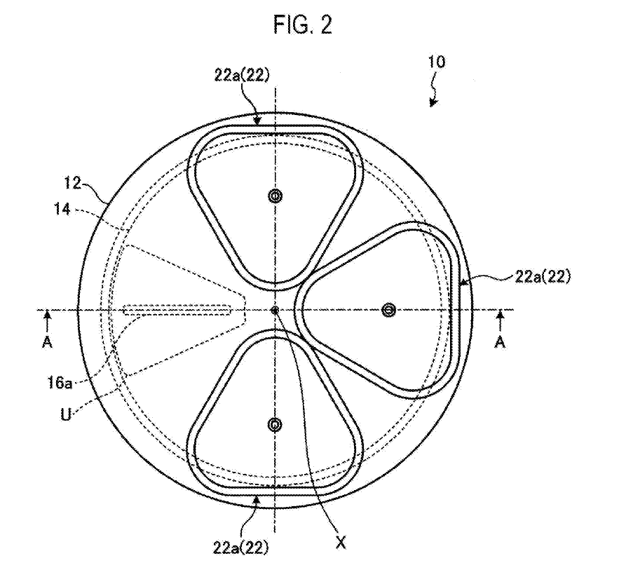

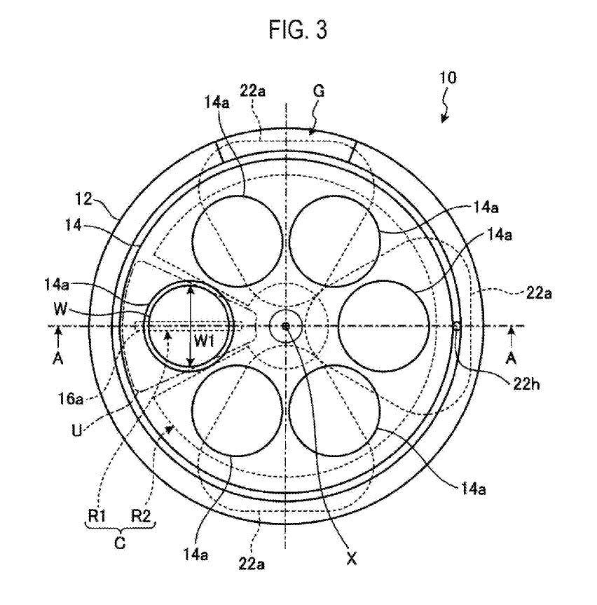

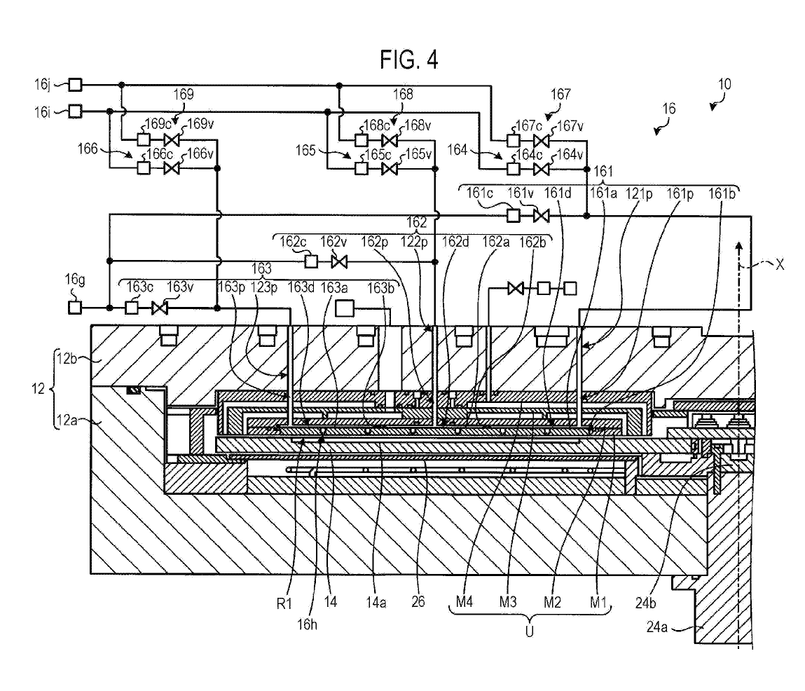

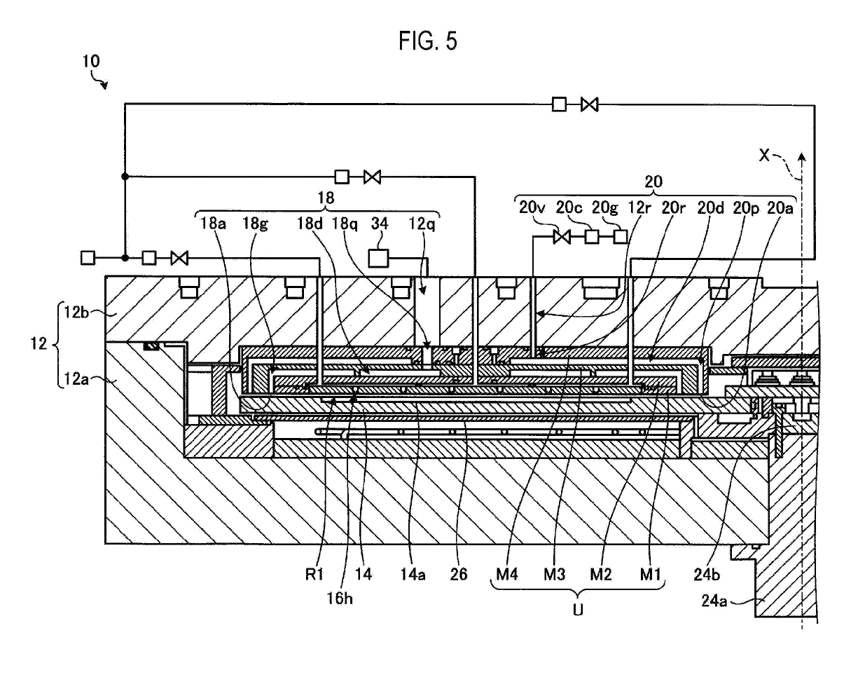

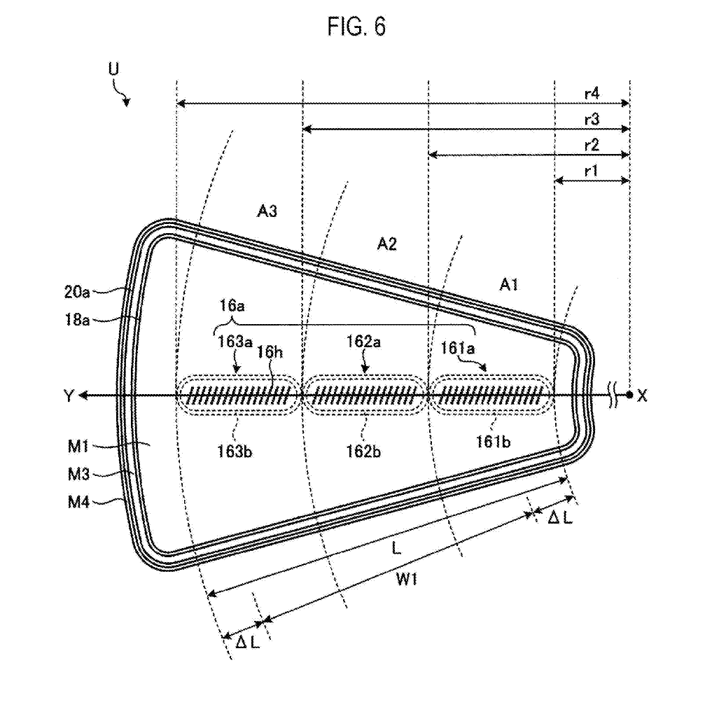

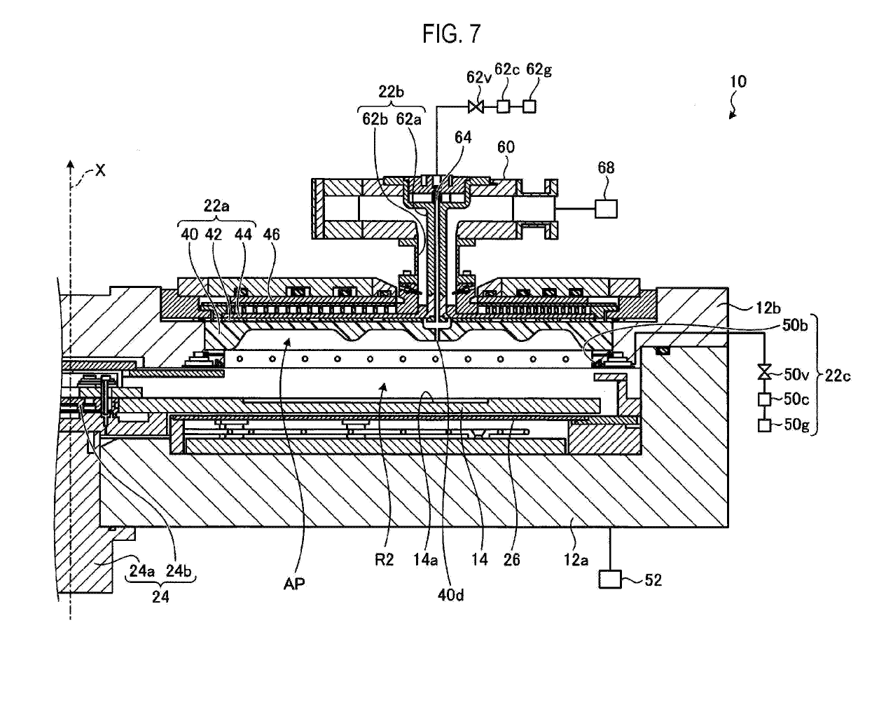

FIG. 1 is a sectional view illustrating one example of a film forming apparatus 10 according to a first embodiment. FIG. 2 is a top view illustrating one example of the film forming apparatus 10 according to the first embodiment. FIG. 3 is a plane view illustrating one example of a state in which a top portion of a process vessel 12 is removed from the film forming apparatus 10 illustrated in FIG. 2. FIG. 1 illustrates a cross section taken along line A-A in FIGS. 2 and 3. FIGS. 4 and 5 are enlarged sectional views illustrating one example of a left portion of an axis X in FIG. 1. FIG. 6 is a view illustrating one example of a lower surface of a unit U. FIG. 7 is an enlarged sectional view illustrating one example of a right portion of an axis X in FIG. 1. The film forming apparatus 10 illustrated in FIGS. 1 to 7 mainly includes a process vessel 12, a mounting table 14, a first gas supply part 16, an exhaust part 18, a second gas supply part 20 and a plasma generation part 22.

As illustrated in FIG. 1, the process vessel 12 includes a lower member 12a and an upper member 12b. The lower member 12a has a substantially cylindrical shape with the upper side thereof opened. The lower member 12a includes a sidewall and a bottom wall which define a recess for forming a process chamber C. The upper member 12b is a lid having a substantially cylindrical shape. The upper member 12b covers and closes an upper opening of the recess of the lower member 12a, thereby forming the process chamber C. An elastic sealing member for hermetically sealing the process chamber C, for example, an O-ring, is installed in a peripheral portion between the lower member 12a and the upper member 12b.

The film forming apparatus 10 includes the mounting table 14 disposed within the process chamber C defined by the process vessel 12. The mounting table 14 is rotationally driven about the axis X by a drive mechanism 24. The drive mechanism 24 includes a drive device 24a such as a motor or the like and a rotary shaft 24b. The drive mechanism 24 is installed on the lower member 12a of the process vessel 12.

The rotary shaft 24b has a center axis coaxial with the axis X and extends into the process chamber C. The rotary shaft 24b is rotated about the axis X by the drive power transmitted from the drive device 24a. The central portion of the mounting table 14 is supported by the rotary shaft 24b. Thus, the mounting table 14 rotates about the axis X together with the rotary shaft 24b. Furthermore, an elastic sealing member such as an O-ring or the like for hermetically sealing the process chamber C is installed between the lower member 12a of the process vessel 12 and the drive mechanism 24.

The film forming apparatus 10 includes a heater 26 disposed under the mounting table 14 within the process chamber C and configured to heat substrates W as workpiece substrates mounted in substrate mounting regions 14a. Specifically, the heater 26 heats the mounting table 14, thereby heating the substrates W.

For example, as illustrated in FIGS. 2 and 3, the process vessel 12 is a substantially cylindrical vessel having a center axis coaxial with the axis X. The process vessel 12 includes the process chamber C defined therein. A unit U provided with an injection part 16a is installed in the process chamber C. The unit U is one example of a shower head. The process vessel 12 is made of metal such as Al (aluminum) or the like with the inner surface thereof subjected to an anti-plasma process, for example, an alumite process or a thermal spray process of Y₂O₃ (yttrium oxide). The film forming apparatus 10 includes a plurality of plasma generation parts 22 disposed within the process vessel 12. Each of the plasma generation parts 22 includes an antenna 22a disposed above the process vessel 12 and configured to output microwaves. In FIGS. 2 and 3, three antennas 22a are installed above the process vessel 12. However, the number of the antennas 22a is not limited thereto but may be two or less or four or more.

For example, as illustrated in FIG. 3, the film forming apparatus 10 includes the mounting table 14 having a plurality of substrate mounting regions 14a defined on the upper surface thereof. The mounting table 14 is a substantially disc-shaped member having a center axis coaxial with the axis X. A plurality of (six, in the example illustrated in FIG. 3) substrate mounting regions 14a for holding the substrates W is formed on the upper surface of the mounting table 14 in a concentric relationship about the axis X. The substrates W are disposed within the substrate mounting regions 14a. The substrate mounting regions 14a support the substrates W so that the substrates W are not misaligned during rotation of the mounting table 14. The substrate mounting regions 14a are substantially circular recesses which are substantially identical in shape with the substantially circular substrates W. The diameter of the recesses of the substrate mounting regions 14a is substantially equal to the diameter W1 of the substrates W mounted in the substrate mounting regions 14a. That is to say, the diameter of the recesses of the substrate mounting regions 14a may be set such that the mounted substrates W are fitted to the recesses and are not displaced from the fitted positions by a centrifugal force even when the mounting table 14 is rotated.

The film forming apparatus 10 includes a gate valve G installed in the outer edge of the process vessel 12 so that the substrates W can be loaded into or unloaded from the process chamber C through the gate valve G by a transfer device such as a robot arm or the like. Furthermore, the film forming apparatus 10 includes an exhaust port 22h formed under the outer edge of the mounting table 14. An exhaust device 52 is connected to the exhaust port 22h. The film forming apparatus 10 controls the operation of the exhaust device 52, thereby maintaining the internal pressure of the process chamber C at a target pressure.

For example, as illustrated in FIG. 3, the process chamber C includes a first region R1 and a second region R2 arranged along the circumferential direction about the axis X. The substrates W mounted in the substrate mounting regions 14a sequentially pass through the first region R1 and the second region R2 upon rotation of the mounting table 14.

### [One Example of a Configuration of Unit U (Shower Head) and Gas Supply/Exhaust Mechanism]

For example, as illustrated in FIGS. 4 and 5, the unit U which supplies and exhausts a gas is disposed above the first region R1 so as to face the upper surface of the mounting table 14. The unit U has a structure in which a first member M1, a second member M2, a third member M3 and a fourth member M4 are stacked one above another. The unit U is installed in the process vessel 12 so as to make contact with the lower surface of the upper member 12b of the process vessel 12.

In the unit U, a gas supply/exhaust mechanism is installed for supplying and exhausting a desired gas to and from the first region R1. The gas supply/exhaust mechanism includes, for example, the first gas supply part 16, the exhaust part 18 and the second gas supply part 20.

### [One Example of a Configuration of First Gas Supply Part 16]

For example, as illustrated in FIG. 4, the first gas supply part 16 includes a first inner gas supply part 161, a first middle gas supply part 162 and a first outer gas supply part 163. For example, as illustrated in FIGS. 1 and 4, the first gas supply part 16 further includes a second inner gas supply part 164, a second middle gas supply part 165 and a second outer gas supply part 166. For example, as illustrated in FIGS. 1 and 4, the first gas supply part 16 further includes a third inner gas supply part 167, a third middle gas supply part 168 and a third outer gas supply part 169.

For example, as illustrated in FIGS. 4 and 5, a gas supply path 161p, a gas supply path 162p and a gas supply path 163p extending through the second member M2 to the fourth member M4 are formed in the unit U. The gas supply path 161p is connected at its upper end to a gas supply path 121p formed in the upper member 12b of the process vessel 12. A gas supply source 16g of a first precursor gas is connected to the gas supply path 121p via a valve 161v and a flow rate controller 161c such as a mass flow controller or the like. The first precursor gas is one example of a process gas. Furthermore, the gas supply path 161p is connected at its lower end to a buffer space 161d formed between the first member M1 and the second member M2 and surrounded by an elastic member 161b, for example, an O-ring. Injection holes 16h of an inner injection part 161a installed in the first member M1 are connected to the buffer space 161d.

Furthermore, the gas supply path 162p is connected at its upper end to a gas supply path 122p formed in the upper member 12b of the process vessel 12. The gas supply source 16g of the first precursor gas is connected to the gas supply path 122p via a valve 162v and a flow rate controller 162c such as a mass flow controller or the like. Furthermore, the gas supply path 162p is connected at its lower end to a buffer space 162d formed between the first member M1 and the second member M2 and surrounded by an elastic member 162b, for example, an O-ring. Injection holes 16h of a middle injection part 162a installed in the first member M1 are connected to the buffer space 162d.

Furthermore, the gas supply path 163p is connected at its upper end to a gas supply path 123p formed in the upper member 12b of the process vessel 12. The gas supply source 16g of the first precursor gas is connected to the gas supply path 123p via a valve 163v and a flow rate controller 163c such as a mass flow controller or the like. Furthermore, the gas supply path 163p is connected at its lower end to a buffer space 163d formed between the first member M1 and the second member M2 and surrounded by an elastic member 163b, for example, an O-ring. Injection holes 16h of an outer injection part 163a installed in the first member M1 are connected to the buffer space 163d.

For example, as illustrated in FIGS. 4 and 5, the buffer space 161d of the first inner gas supply part 161, the buffer space 162d of the first middle gas supply part 162 and the buffer space 163d of the first outer gas supply part 163 form independent spaces. The flow rates of the first precursor gas flowing through the respective buffer spaces are independently controlled by the flow rate controller 161c, the flow rate controller 162c and the flow rate controller 163c.

The first gas supply part 16 supplies a first precursor gas to the first region R1 using the first inner gas supply part 161, the first middle gas supply part 162 and the first outer gas supply part 163 configured as above.

Furthermore, the first gas supply part 16 supplies a purge gas to the first region R1 using the second inner gas supply part 164, the second middle gas supply part 165 and the second outer gas supply part 166. The second inner gas supply part 164 includes a valve 164v and a flow rate controller 164c such as a mass flow controller or the like. A gas supply source 16i of a purge gas is connected to the gas supply path 121p via the valve 164v and the flow rate controller 164c. Furthermore, the second middle gas supply part 165 includes a valve 165v and a flow rate controller 165c such as a mass flow controller or the like. The gas supply source 16i of the purge gas is connected to the gas supply path 122p via the valve 165v and the flow rate controller 165c. Moreover, the second outer gas supply part 166 includes a valve 166v and a flow rate controller 166c such as a mass flow controller or the like. The gas supply source 16i of the purge gas is connected to the gas supply path 123p via the valve 166v and the flow rate controller 166c.

Furthermore, the first gas supply part 16 supplies a second precursor gas to the first region R1 using the third inner gas supply part 167, the third middle gas supply part 168 and the third outer gas supply part 169. The third inner gas supply part 167 includes a valve 167v and a flow rate controller 167c such as a mass flow controller or the like. A gas supply source 16j of a second precursor gas is connected to the gas supply path 121p via the valve 167v and the flow rate controller 167c. Furthermore, the third middle gas supply part 168 includes a valve 168v and a flow rate controller 168c such as a mass flow controller or the like. The gas supply source 16j of the second precursor gas is connected to the gas supply path 122p via the valve 168v and the flow rate controller 168c. Moreover, the third outer gas supply part 169 includes a valve 169v and a flow rate controller 169c such as a mass flow controller or the like. The gas supply source 16j of the second precursor gas is connected to the gas supply path 123p via the valve 169v and the flow rate controller 169c.

The second inner gas supply part 164, the second middle gas supply part 165 and the second outer gas supply part 166 of the first gas supply part 16 serve just like the first inner gas supply part 161, the first middle gas supply part 162 and the first outer gas supply part 163, respectively. Furthermore, the third inner gas supply part 167, the third middle gas supply part 168 and the third outer gas supply part 169 of the first gas supply part 16 serve just like the first inner gas supply part 161, the first middle gas supply part 162 and the first outer gas supply part 163, respectively.

The first precursor gas forms a Si film on the surface of the substrate W passing through the first region R1. The first precursor gas may be, for example, monochlorosilane, dichlorosilane (DCS), trichlorosilane, tetrachlorosilane or hexachlorodisilane (HCD). The first precursor gas is supplied to the first region R1. Atoms or molecules of the first precursor gas are chemisorbed onto the surface of the substrate W passing through the first region R1.

Furthermore, the second precursor gas nitrides the Si film formed on the surface of the substrate W passing through the first region R1 and adds carbon to the Si film. Thus, the Si film is changed to a SiCN film. The second precursor gas may be, for example, a gas containing nitrogen and carbon. The second precursor gas may be, for example, a gas including a carbon-containing nitriding agent. The second precursor gas is pyrolyzed in a temperature zone of, for example, 200 degrees C. or more and 550 degrees C. or less, thereby generating an active decomposition product. Examples of the second precursor gas will be described later in detail.

The purge gas is used to remove a process gas from the gas supply parts. The purge gas may be, for example, a gas that does not incur a chemical reaction. The purge gas may be, for example, an inert gas such as argon (Ar) or the like. Furthermore, the purge gas may be, for example, a mixed gas of an Ar gas and an N₂ gas.

As described above, in the unit U, the first inner gas supply part 161, the first middle gas supply part 162 and the first outer gas supply part 163 of the first gas supply part 16 supply the first precursor gas into the first region R1. The second inner gas supply part 164, the second middle gas supply part 165 and the second outer gas supply part 166 of the first gas supply part 16 supply the purge gas into the first region R1. The third inner gas supply part 167, the third middle gas supply part 168 and the third outer gas supply part 169 of the first gas supply part 16 supply the second precursor gas into the first region R1.

In this way, by supplying the purge gas after supplying the first precursor gas, it is possible to remove the gas remaining within the gas supply/exhaust mechanism. This makes it possible to supply plural kinds of desired gases to the first region R1 while preventing mixture of the first precursor gas and the second precursor gas. In the case where a process is not affected by the mixture of the first precursor gas and the second precursor gas, it is not necessary to install a plurality of gas supply/exhaust mechanisms. For example, it may be possible to employ a configuration in which plural kinds of gases are supplied by the first inner gas supply part 161, the first middle gas supply part 162 and the first outer gas supply part 163.

### [One Example of a Configuration of Second Gas Supply Part 20]

Next, descriptions will be made on the second gas supply part 20 which supplies a purge gas to a peripheral edge portion of the first region R1.

As illustrated in FIGS. 4 and 5, a gas supply path 20r extending through the fourth member M4 is formed in the unit U. The gas supply path 20r is connected at its upper end to a gas supply path 12r formed in the upper member 12b of the process vessel 12. A gas supply source 20g of a purge gas is connected to the gas supply path 12r via a valve 20v and a flow rate controller 20c.

The gas supply path 20r is connected at its lower end to a space 20d formed between the lower surface of the fourth member M4 and the upper surface of the third member M3. Furthermore, the fourth member M4 defines a recess that accommodates the first member M1 to the third member M3. A gap 20p is formed between the inner surface of the fourth member M4 defining the recess and the outer surface of the third member M3. The gap 20p is connected to the space 20d. The lower end of the gap 20p serves as an injection hole 20a.

Since the injection hole 20a is formed near the outer edge of the unit U as described above, the first precursor gas and the second precursor gas injected from the injection holes 16h formed nearer to the center of the unit U are prevented from flowing out of the first region R1.

### [One Example of a Configuration of Exhaust Part 18]

Next, descriptions will be made on one example of the exhaust part 18 which exhausts the purge gas injected from the peripheral edge portion of the first region R1 and exhausts the first precursor gas, the second precursor gas and the purge gas injected from the central portion of the first region R1.

For example, as illustrated in FIGS. 4 and 5, an exhaust path 18q extending through the third member M3 and the fourth member M4 is formed in the unit U. The exhaust path 18q is connected at its upper end to an exhaust path 12q formed in the upper member 12b of the process vessel 12. The exhaust path 12q is connected to the exhaust device 34 such as a vacuum pump or the like. Furthermore, the exhaust path 18q is connected at its lower end to a space 18d formed between the lower surface of the third member M3 and the upper surface of the second member M2.

The third member M3 includes a recess that accommodates the first member M1 and the second member M2. A gap 18g is formed between the inner surface of the third member M3, which defines the recess of the third member M3, and the outer surfaces of the first member M1 and the second member M2. The space 18d is connected to the gap 18g. The lower end of the gap 18g serves as an exhaust port 18a.

As described above, the exhaust port 18a is formed between the injection hole 20a from which the purge gas is injected and the injection holes 16h from which the first and second precursor gases are injected. This makes it possible to efficiently exhaust the purge gas, the first precursor gas and the second precursor gas.

[One Example of Arrangement of Injection Part 16a]

For example, as illustrated in FIG. 6, the injection part 16a is installed on the lower surface of the unit U, which faces the mounting table 14, along a Y-axis direction extending away from the axis X. The region facing the injection part 16a among the regions included in the process chamber C is the first region R1. The first region R1 is one example of an adsorption/reaction process region. The injection part 16a injects precursor gases toward the substrates W mounted on the mounting table 14. For example, as illustrated in FIG. 6, the injection part 16a includes the inner injection part 161a, the middle injection part 162a and the outer injection part 163a.

For example, as illustrated in FIG. 6, the inner injection part 161a is formed within an inner annular region A1 included in the lower surface of the unit U among an annular region existing within a range of distance r1 to r2 from the axis X. Furthermore, the middle injection part 162a is formed within a middle annular region A2 included in the lower surface of the unit U among an annular region existing within a range of distance r2 to r3 from the axis X. Moreover, the outer injection part 163a is formed within an outer annular region A3 included in the lower surface of the unit U among an annular region existing within a range of distance r3 to r4 from the axis X.

The radius r4 of the outer circumference of the outer annular region A3 is larger than the radius r3 of the outer circumference of the middle annular region A2. Furthermore, the radius r3 of the outer circumference of the middle annular region A2 is larger than the radius r2 of the outer circumference of the inner annular region A1. The inner annular region A1, the middle annular region A2 and the outer annular region A3 are one example of a first annular region.

For example, as illustrated in FIG. 6, the length L from r1 to r4, which is the Y-direction extension range of the injection part 16a formed on the lower surface of the unit U, is larger than the Y-axis passing length of the substrate W having a diameter W1, by a predetermined distance ΔL or more in the direction extending toward the axis X and by a predetermined distance ΔL or more in the direction extending away from the axis X. The predetermined distance ΔL is determined by the distance between the substrate W and the unit U in the direction of the axis X. In the present embodiment, the predetermined distance ΔL may be, for example, several millimeters. The predetermined distance ΔL is one example of a second distance.

For example, as illustrated in FIG. 6, each of the inner injection part 161a, the middle injection part 162a and the outer injection part 163a includes a plurality of injection holes 16h. The first precursor gas and the second precursor gas are injected from the respective injection holes 16h to the first region R1. As the first precursor gas and the second precursor gas are supplied to the first region R1, a film is formed on the surface of the substrate W passing through the first region R1, by the atoms or molecules of the first precursor gas and the second precursor gas.

In the present embodiment, in order to enable injection of the precursor gases at different flow rates from the inner injection part 161a and the middle injection part 162a, for example, as illustrated in FIGS. 4 and 5, the elastic member 161b and the elastic member 162b are disposed between the buffer space 161d of the first inner gas supply part 161 and the buffer space 162d of the first middle gas supply part 162. Similarly, the elastic member 162b and the elastic member 163b are disposed between the buffer space 162d of the first middle gas supply part 162 and the buffer space 163d of the first outer gas supply part 163. Thus, in the unit U according to the present embodiment, for example, as illustrated in FIG. 6, a gap (of, for example, about several millimeters) corresponding to the region where the elastic member 161b and the elastic member 162b are disposed exists in the Y-axis direction between the injection holes 16h included in the inner injection part 161a and the injection holes 16h included in the middle injection part 162a. Similarly, a gap (of, for example, about several millimeters) corresponding to the region where the elastic member 162b and the elastic member 163b are disposed exists in the Y-axis direction between the injection holes 16h included in the middle injection part 162a and the injection holes 16h included in the outer injection part 163a.

For example, as illustrated in FIGS. 4 and 5, the exhaust port 18a of the exhaust part 18 is formed above the first region R1 so as to face the upper surface of the mounting table 14. For example, as illustrated in FIG. 6, the exhaust port 18a is formed on the lower surface of the unit U so as to surround the periphery of the injection part 16a. The gases existing within the process chamber C are exhausted through the exhaust port 18a by the operation of the exhaust device 34 such as a vacuum pump or the like.

For example, as illustrated in FIGS. 4 and 5, the injection hole 20a of the second gas supply part 20 is formed above the first region R1 so as to face the upper surface of the mounting table 14. For example, as illustrated in FIG. 6, the injection hole 20a is formed on the lower surface of the unit U so as to surround the periphery of the exhaust port 18a. The second gas supply part 20 injects the purge gas to the first region R1 through the injection hole 20a. The purge gas injected by the second gas supply part 20 may be, for example, an inert gas such as Ar (argon) or the like. As the purge gas is injected toward the surface of the substrate W, the atoms or molecules of the first precursor gas and the second precursor gas (the remaining gas components) excessively adhering to the substrate W are removed from the substrate W. Thus, an atomic layer or a molecular layer of the atoms or molecules of the first precursor gas and the second precursor gas are formed on the surface of the substrate W.

The unit U injects the purge gas from the injection hole 20a and exhausts the purge gas from the exhaust port 18a along the surface of the mounting table 14. Thus, the unit U restrains the first precursor gas and the second precursor gas supplied to the first region R1 from being leaked out of the first region R1. Since the unit U injects the purge gas from the injection hole 20a and exhausts the purge gas from the exhaust port 18a along the surface of the mounting table 14, it is possible for the unit U to restrain the modifying gas or radicals of the modifying gas supplied to the second region R2 from entering the first region R1. That is to say, the unit U separates the first region R1 and the second region R2 by injecting the purge gas from the second gas supply part 20 and exhausting the purge gas from the exhaust part 18.

### [One Example of Configuration of Plasma Generation Part 22]

For example, as illustrated in FIG. 7, the film forming apparatus 10 includes the plasma generation part 22 installed in an aperture AP of the upper member 12b existing above the second region R2 so as to face the upper surface of the mounting table 14. The plasma generation part 22 includes the antenna 22a and a coaxial waveguide 22b configured to supply microwaves and a modifying gas to the antenna 22a. For example, three apertures AP are formed in the upper member 12b. The film forming apparatus 10 includes, for example, three plasma generation parts 22.

The plasma generation part 22 supplies a modifying gas and microwaves to the second region R2 to generate plasma of the modifying gas in the second region R2. The nitride film formed on the surface of the substrate W can be modified by an active species generated by the plasma of the modifying gas. As the modifying gas, it may be possible to use, for example, one of an N₂ gas, an NH₃ gas, an Ar gas, an H₂ gas and a He gas, or a mixed gas obtained by appropriately mixing these gases. In the present embodiment, an Ar gas is used as the modifying gas. At a modifying step, the flow rate of the Ar gas may be, for example, 150 sccm.

For example, as illustrated in FIG. 7, in the plasma generation part 22, the antenna 22a is air-tightly disposed so as to close the aperture AP. The antenna 22a includes a top plate 40, a slot plate 42 and a slow-wave plate 44. The top plate 40 is a member having a substantially equilateral triangle shape formed of a dielectric body. The top plate 40 may be made of, for example, alumina or ceramic. The top plate 40 is supported by the upper member 12b so that the lower surface thereof is exposed to the second region R2 from the aperture AP formed in the upper member 12b of the process vessel 12. An injection hole 40d extending through the top plate 40 in the thickness direction is formed on the lower surface of the top plate 40.

The slot plate 42 is disposed on the upper surface of the top plate 40. The slot plate 42 is a plate-shaped metal-made member having a substantially equilateral triangle shape. The slot plate 42 has an opening formed in a position overlapping with the injection hole 40d in the direction of the axis X. Furthermore, the slot plate 42 has plural pairs of slots. Each of the slot pairs includes two slot holes orthogonal to each other or intersecting each other.

The slow-wave plate 44 is installed on the upper surface of the slot plate 42. The slow-wave plate 44 is a member having a substantially equilateral triangle shape formed of a dielectric body. The slow-wave plate 44 may be made of, for example, alumina or ceramic. The slow-wave plate 44 has a substantially cylindrical opening in which an outer conductor 62b of the coaxial waveguide 22b is disposed.

A metal-made cooling plate 46 is installed on the upper surface of the slow-wave plate 44. The cooling plate 46 cools the antenna 22a through the slow-wave plate 44 using a coolant which flows through a flow path formed within the cooling plate 46. The cooling plate 46 is pressed against the upper surface of the slow-wave plate 44 by a spring or the like not shown in the drawings. Thus, the lower surface of the cooling plate 46 makes close contact with the upper surface of the slow-wave plate 44.

The coaxial waveguide 22b includes an inner conductor 62a and the outer conductor 62b which have a substantially cylindrical hollow shape. The inner conductor 62a extends from the upper side of the antenna 22a and passes through the opening of the slow-wave plate 44 and the opening of the slot plate 42. A space 64 formed within the inner conductor 62a communicates with the injection hole 40d of the top plate 40. Furthermore, a gas supply source 62g of a modifying gas is connected to the upper end of the inner conductor 62a via a valve 62v and a flow rate control part 62c such as a mass flow controller or the like. The modifying gas supplied from the valve 62v to the coaxial waveguide 22b passes through the space 64 formed within the inner conductor 62a. Then, the modifying gas is injected from the injection hole 40d of the top plate 40 to the second region R2.

The outer conductor 62b is installed so as to surround the inner conductor 62a with a gap left between the outer circumferential surface of the inner conductor 62a and the inner circumferential surface of the outer conductor 62b. The lower end of the outer conductor 62b is connected to an opening portion of the cooling plate 46.

The film forming apparatus 10 includes a waveguide 60 and a microwave generator 68. Microwaves of, for example, 2.45 GHz, generated by the microwave generator 68 are propagated to the coaxial waveguide 22b through the waveguide 60 and are propagated through a gap between the inner conductor 62a and the outer conductor 62b. The microwaves propagated through the slow-wave plate 44 are propagated from the slot holes of the slot plate 42 to the top plate 40 and are radiated from the top plate 40 to the second region R2.

Furthermore, a modifying gas is also supplied from a modifying gas supply part 22c to the second region R2. The modifying gas supply part 22c includes injection parts 50b. For example, the injection parts 50b are installed inside the upper member 12b of the process vessel 12 so as to extend around the aperture AP. The injection parts 50b inject the modifying gas supplied from the gas supply source 50g toward the second region R2 existing under the top plate 40. The gas supply source 50g of the modifying gas is connected to the injection parts 50b via a valve 50v and a flow rate control part 50c such as a mass flow controller or the like.

In the embodiment of the film forming apparatus 10 illustrated in FIG. 7, the modifying gas supply part 22c is installed so as to supply a gas differing from the gas supplied from the gas supply source 62g. By employing this configuration, it is possible to use plural kinds of gases as the modifying gas. However, the present disclosure is not limited thereto. The film forming apparatus 10 may be configured so as to supply only one kind of gas. Furthermore, as will be described later, a gas used in a process other than the modifying process may be supplied from the gas supply source 62g or the gas supply source 50g.

In the plasma generation part 22, the modifying gas is supplied to the second region R2 by the injection hole 40d of the top plate 40 and the injection parts 50b of the modifying gas supply part 22c. The microwaves are radiated to the second region R2 by the antenna 22a. Thus, the plasma generation part 22 generates plasma of the modifying gas in the second region R2.

As will be described later, in the first embodiment, when forming a SiCN film, an Ar gas is supplied to the second region R2 during a purge process and a modifying process. Furthermore, when forming an SiOCN film, an O₂ gas is supplied to the second region R2 in order to supply oxygen molecules to the substrate. The Ar gas is supplied to the second region R2 during the purge process and the modifying process. Thus, the film forming apparatus 10 is configured such that the Ar gas is supplied from the modifying gas supply part 22c of the plasma generation part 22 and such that the O₂ gas is supplied from the gas supply source 62g. The gas to be supplied may be switched in response to a control signal transmitted from a control part 70 which will be described later.

For example, as illustrated in FIG. 1, the film forming apparatus 10 includes the control part 70 for controlling the respective components of the film forming apparatus 10. The control part 70 may be a computer which includes a control device such as a central processing unit (CPU) or the like, a memory device such as a memory or the like, and an input/output device. The control part 70 controls the respective components of the film forming apparatus 10 by allowing the CPU to operate according to a control program stored in the memory.

The control part 70 transmits a control signal, which controls the rotation speed of the mounting table 14, to the drive device 24a. Furthermore, the control part 70 transmits a control signal, which controls the temperature of the substrate W, to a power source connected to the heater 26. Furthermore, the control part 70 transmits a control signal, which controls the flow rates of the first precursor gas, the second precursor gas and the purge gas supplied by the first gas supply part 16, to the valves 161v to 169v and the flow rate controllers 161c to 169c. Furthermore, the control part 70 transmits a control signal, which controls the exhaust amount of the exhaust device 34 connected to the exhaust port 18a, to the exhaust device 34.

Furthermore, the control part 70 transmits a control signal, which controls the flow rate of the purge gas, to the valve 20v and the flow rate controller 20c. Furthermore, the control part 70 transmits a control signal, which controls the generation power of microwaves, to the microwave generator 68. Furthermore, the control part 70 transmits a control signal, which controls the flow rate of the modifying gas, to the valve 50v, the valve 62v, the flow rate control part 50c and the flow rate control part 62. Furthermore, the control part 70 transmits a control signal, which controls the exhaust amount from the exhaust port 22h, to the exhaust device 52.

In the film forming apparatus 10 configured as above, as the mounting table 14 makes rotation, the first precursor gas is injected from the first gas supply part 16 onto the substrate W passing through the first region R1. The excessively-chemisorbed first precursor gas is removed from the substrate W by the second gas supply part 20. Then, when the substrate W passes through the first region R1 again along with the rotation of the mounting table 14, the second precursor gas is injected from the first gas supply part 16. Then, when the substrate W passes through the second region R2 along with the rotation of the mounting table 14, the substrate W is exposed to the plasma of the modifying gas generated by the plasma generation part 22. The film forming apparatus 10 forms a film having a predetermined thickness on the substrate W by repeating the aforementioned operation with respect to the substrate W.

Furthermore, in the film forming apparatus 10 configured as above, as the mounting table 14 makes rotation, the first precursor gas is injected from the first gas supply part 16 onto the substrate W passing through the first region R1. Then, when the substrate W passes through the first region R1 again along with the rotation of the mounting table 14, the second precursor gas is injected from the first gas supply part 16 to the substrate W passing through the first region R1. Then, when the substrate W passes through the second region R2 along with the rotation of the mounting table 14, a third gas (e.g., an O₂ gas) supplied from the plasma generation part 22 is injected onto the substrate W. Then, when the substrate W passes through the second region R2 again along with the rotation of the mounting table 14, the substrate W is exposed to the plasma of the modifying gas generated by the plasma generation part 22. The film forming apparatus 10 forms a film having a predetermined thickness on the substrate W by repeating the aforementioned operation with respect to the substrate W.

### [One Example of a Second Precursor Gas]

In the first embodiment, the first precursor gas and the second precursor gas are supplied to the first region R1, thereby forming a SiCN film or a SiOCN film. At this time, when forming the SiCN film or the SiOCN film, nitriding can be realized using heat treatment without using plasma.

In the case where a SiC film is nitrided without using plasma, the deposition temperature is set low. However, if the deposition temperature falls within a temperature zone of, for example, less than 630 degrees C., the deposition rate is sharply reduced as compared with a case where plasma is used. Thus, in order to maintain a high deposition rate while reducing the deposition temperature, a gas to be described below may be used as the second precursor gas.

Hereinafter, as one example of the second precursor gas, a gas including a carbon-containing nitriding agent will be described. The gas includes a nitriding agent. The nitriding agent is a compound of nitrogen and carbon, which is represented by the following chemical formula (1).

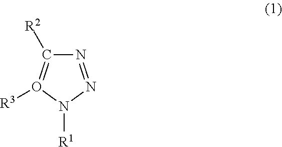

In chemical formula (1), R′, R² and R³ are linear or branched alkyl groups having 1 to 8 carbon atoms, which may have hydrogen atoms or substituents. The compound represented by chemical formula (1) is a 1,2,3-triazole-based compound.

Examples of the linear or branched alkyl groups having 1 to 8 carbon atoms may include a methyl group, an ethyl group, an n-propyl group, an isopropyl group, an n-butyl group, an isobutyl group, a t-butyl group, an n-pentyl group, an isopentyl group, a t-pentyl group, an n-hexyl group, an isohexyl group, a t-hexyl group, an n-heptyl group, an isoheptyl group, a t-heptyl group, an n-octyl group, an isooctyl group and a t-octyl group. Specifically, the linear or branched alkyl groups may be the methyl group, the ethyl group or the n-propyl group. More specifically, the linear or branched alkyl groups may be the methyl group.

Furthermore, the substituent may be a linear or branched monoalkylamino group or dialkylamino group substituted with an alkyl group having 1 to 4 carbon atoms. For example, the substituent may be a monomethylamino group, a dimethylamino group, a monoethylamino group, a diethylamino group, a monopropylamino group, a monoisopropylamino group or an ethylmethylamino group. Specifically, the substituent may be the monomethylamino group or the dimethylamino group. More specifically, the substituent may be the dimethylamino group.

Furthermore, the substituent may be a linear or branched alkoxy group having 1 to 8 carbon atoms. For example, the substituent may be a methoxy group, an ethoxy group, a propoxy group, a butoxy group, a pentoxy group, a hexyloxy group, a heptyloxy group or an octyloxy group. Specifically, the substituent may be the methoxy group, the ethoxy group or the propoxy group. More specifically, the substituent may be the methoxy group.

Examples of the specific compound represented by chemical formula (1) may include 1H-1,2,3-triazole, 1-methyl-1,2,3-triazole, 1,4-dimethyl-1,2,3-triazole, 1,4,5-trimethyl-1,2,3 triazole, 1-ethyl-1,2,3-triazole, 1,4-diethyl-1,2,3-triazole and 1,4,5-triethyl-1,2,3-triazole. These compounds may be used either independently or in combination.

In the case where the gas including a carbon-containing nitriding agent is used as the second precursor gas, the nitriding and the C adding can be simultaneously performed during the same step using one kind of compound. This is because the 1,2,3-triazole-based compound contains N atoms and C atoms. Thus, a step of carbonizing a Si film or a step of carbonizing a SiN film becomes unnecessary. It is therefore possible to enhance the throughput.

Furthermore, in the case where the gas including a carbon-containing nitriding agent is used as the second precursor gas, it is possible to maintain a high deposition rate even when the deposition temperature is reduced.

The 1,2,3-triazole-based compound contains an “N═N—N” bond within a five-membered ring. In the “N═N—N” bond, the “N═N” portion tends to be decomposed to become nitrogen (N₂, N═N). Thus, the 1,2,3-triazole-based compound, unlike the usual ring-opening cleavage, has a tendency to undergo cleavage and decomposition at a plurality of points. That is to say, the 1,2,3-triazole-based compound generates “N≡N”. Thus, an electronically unsaturated state occurs within the compound. A decomposition product obtained as a result of cleavage and decomposition of the 1,2,3-triazole-based compound is active. For that reason, even when the deposition temperature is low and falls within a temperature range of, for example, 200 degrees C. or more and 550 degrees C. or less, it is possible to nitride a Si film and, ultimately, to add C.

Furthermore, in the case where a film is formed using the gas including a carbon-containing nitriding agent, it is possible to produce a C-rich SiCN film. Furthermore, the additional amount of C can be adjusted by controlling the flow rate of the 1,2,3-triazole-based compound. Thus, after producing the C-rich film, a modifying process is performed using plasma, thereby removing easily-desorbed C. In this state, a film forming process is further performed. This makes it possible to improve film quality.

### [One Example of a Flow of the Film Forming Process According to the First Embodiment (in the Case of SiCN Film)]

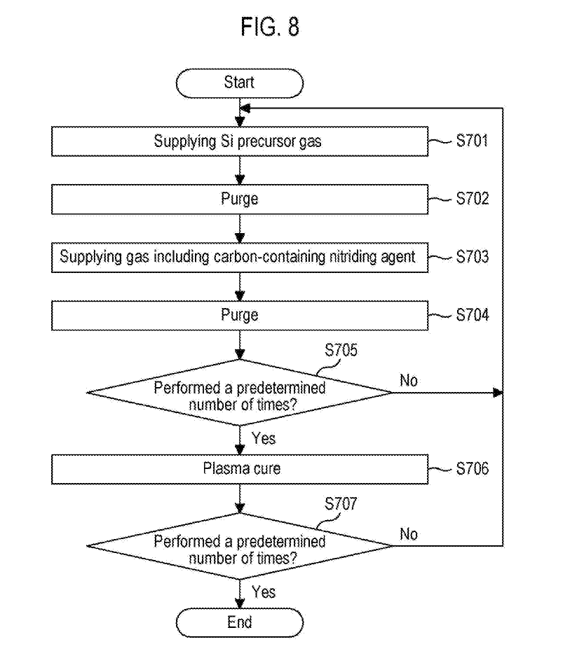

Next, one example of a flow of a film forming process of a SiCN film using the film forming apparatus 10 according to the first embodiment will be described with reference to FIG. 8. FIG. 8 is a flowchart illustrating a flow of one example of a film forming process of a SiCN film implemented in the film forming apparatus 10 according to the first embodiment.

In the film forming process illustrated in FIG. 8, a silicon wafer having a SiO₂ film formed on the surface thereof may be used as the substrate W. However, the film formed on the substrate W is not limited to the SiO₂ film but may be any film that enables formation of a SiCN film. Hexachlorodisilane (HCD) may be used as a Si precursor gas which is the first precursor gas. As the second precursor gas, it may be possible to use a gas including the aforementioned 1H-1,2,3-triazole as the carbon-containing nitriding agent.

As illustrated in FIG. 8, in the case of forming a SiCN film on the substrate W, the substrate W is first mounted in each of the substrate mounting regions 14a and then the operation of the film forming apparatus 10 is started. That is to say, the control of the film forming apparatus 10 using the control part 70 is started. As the mounting table 14 rotates, the substrate W is first moved into the first region R1. At this time, in the first gas supply part 16, the respective valves and the respective flow rate controllers are controlled so that the first precursor gas is supplied to the first region R1. Then, the first precursor gas is supplied by the first gas supply part 16 (the first inner gas supply part 161, the first middle gas supply part 162 and the first outer gas supply part 163) and is injected toward the substrate W (step S701). The first precursor gas is a Si precursor gas. By virtue of step S701, a Si film is formed on the substrate W.

After the substrate W has passed through the first region R1, the respective valves and the respective flow rate controllers of the first gas supply part 16 are controlled so that the purge gas is supplied. Then, the first precursor gas remaining in the supply system of the first gas supply part 16 is purged (step S702).

If the substrate W is moved into the first region R1 again, the respective valves and the respective flow rate controllers of the first gas supply part 16 are controlled so as to supply the second precursor gas. Then, the first gas supply part 16 (the third inner gas supply part 167, the third middle gas supply part 168 and the third outer gas supply part 169) supplies the second precursor gas and injects the second precursor gas toward the substrate W (step S703). The second precursor gas may be, for example, a gas including a carbon-containing nitriding agent. By virtue of step S703, a SiCN film is formed on the substrate W.

After the substrate W has passed through the first region R1, the respective valves and the respective flow rate controllers of the first gas supply part 16 are controlled so that the purge gas is supplied. Then, the second precursor gas remaining in the supply system of the first gas supply part 16 is purged (step S704).

Subsequently, the film forming apparatus 10, namely the control part 70, determines whether the processes of steps S701 to S704 have been performed a predetermined number of times (step S705). If the control part 70 determines that the processes of steps S701 to S704 have not been performed a predetermined number of times (if “No” at step S705), the flow comes back to step S701 where the supply of the first precursor gas is performed by the first gas supply part 16. On the other hand, if it is determined that the processes of steps S701 to S704 have been performed a predetermined number of times (if “Yes” at step S705), the control part 70 causes the plasma generation part 22 to supply the modifying gas, thereby performing a plasma cure (modifying process) (step S706). Then, the control part 70 determines whether the plasma cure has been performed a predetermined number of times (step S707). If it is determined that the plasma cure has not been performed a predetermined number of times (if “No” at step S707), the control part 70 controls the film forming apparatus 10 so as to perform the process of step S701 again. On the other hand, if it is determined that the plasma cure has been performed a predetermined number of times (if “Yes” at step S707), the control part 70 terminates the processes.

In this way, the first precursor gas and the second precursor gas are supplied to the first region R1 and the modifying gas for the modifying process is supplied to the second region R2. That is to say, the thermal process and the modifying process using plasma are combined and realized in the semi-batch apparatus. Furthermore, the plasma generation part 22 may be configured such that when not performing the plasma cure, an Ar gas is supplied and exhausted to perform a purge operation. In the unit U, the exhaust part 18 and the second gas supply part 20 are always operated during the process to prevent the first precursor gas and the second precursor gas from flowing out of the first region R1 and to prevent the plasma from entering the first region R1.

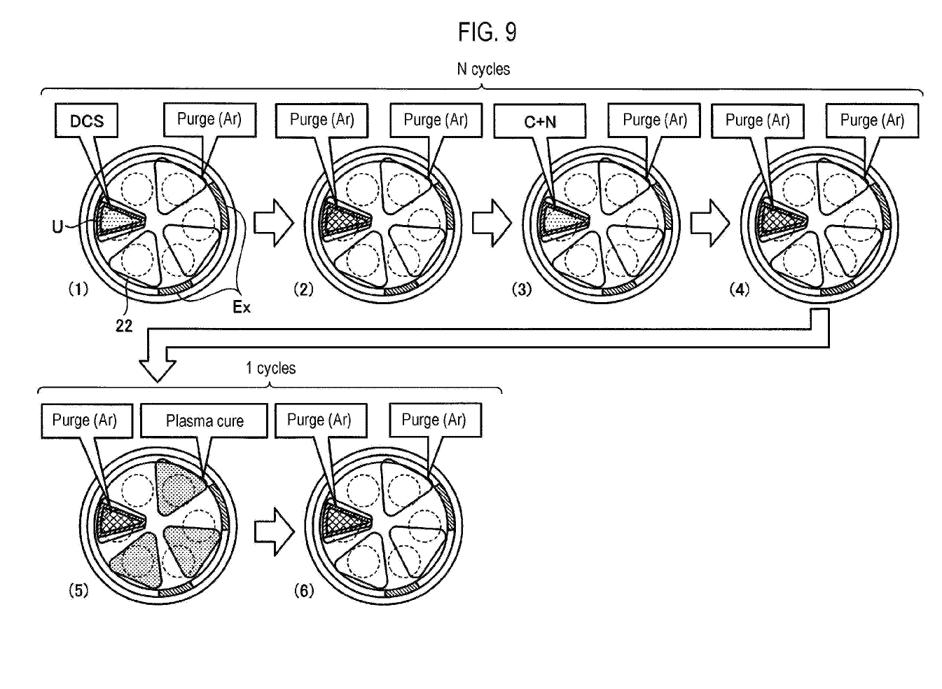

FIG. 9 is a schematic view for explaining the flow of one example of the film forming process of the SiCN film implemented in the film forming apparatus 10 according to the first embodiment. One example of the film forming process of the SiCN film performed in the film forming apparatus 10 will be described again with reference to FIG. 9.

As illustrated in FIG. 9, if the film forming process is started, when the mounting table 14 makes a first rotation, a Si precursor gas as the first precursor gas, namely DCS, is injected onto the substrate W by the first gas supply part 16 ((1) in FIG. 9). When injecting the DCS, the supply of the purge gas using the second gas supply part 20 and the exhaust using the exhaust part 18 are also performed. The substrate W passed through the first region R1 passes through the plasma region, namely the second region R2. At this time, the plasma generation part 22 is controlled so as to supply an Ar gas as the purge gas without performing the generation and supply of the modifying plasma ((1) in FIG. 9). By the process performed during the first rotation, a Si film is formed on the substrate W.

If the mounting table 14 comes into a second rotation, the first gas supply part 16 is controlled so as to supply the purge gas to the first region R1 ((2) in FIG. 9). The reason for supplying the purge gas from the first gas supply part 16 at this step is to purge the first precursor gas remaining within the first gas supply part 16 and to prevent the first precursor gas from being mixed with the second precursor gas supplied at the third rotation of the mounting table 14. Even at the second rotation, similar to the first rotation, the Ar gas is supplied to the plasma region to perform a purge operation.

If the mounting table 14 comes into a third rotation, the first gas supply part 16 supplies a gas (C+N) including a carbon-containing nitriding agent, which is the second precursor gas, to the first region R1 ((3) in FIG. 9). Thus, the Si film formed on the substrate W is nitrided and carbon is implanted into the substrate w, whereby a SiCN film is formed. At this time, ammonia (NH₃) may be supplied together with the gas including a carbon-containing nitriding agent. By supplying NH₃ together with the gas including a carbon-containing nitriding agent, it is possible to increase the deposition rate. Particularly, in the case where it is difficult to increase a gas flow rate by increasing a vapor pressure in the second region R2, the use of NH₃ makes it possible to increase the production efficiency. Even at the third rotation, similar to the first and second rotations, the Ar gas is supplied to the plasma region to perform a purge operation.

At a fourth rotation, similar to the second rotation, the first gas supply part 16 supplies the Ar gas as the purge gas to the first region R1 to perform a purge operation. Similarly, the Ar gas is also supplied to the plasma region to perform a purge operation ((4) in FIG. 9).

The processes (1) to (4) in FIG. 9 are repeatedly performed until a SiCN film having a predetermined film thickness is formed. In the example illustrated in FIG. 9, the processes (1) to (4) are performed N cycles (where N is an arbitrary natural number).

If a SiCN film having a predetermined thickness is formed by performing the processes (1) to (4) in FIG. 9 N cycles, at the next rotation, the purge gas is supplied to the first region R1 by the first gas supply part 16. Furthermore, the modifying gas is supplied to the plasma region, namely the second region R2, by the plasma generation part 22 to generate plasma of the modifying gas ((5) in FIG. 9). Then, the SiCN film formed on the substrate W is exposed to the plasma of the modifying gas, whereby the carbon atoms not sufficiently adsorbed to the substrate W are removed from the substrate W. In the example of the process (5) illustrated in FIG. 9, the modifying process is performed in all three plasma generation parts 22 provided in the film forming apparatus 10. However, the present disclosure is not limited thereto. The modifying process may be performed only in one or two plasma generation parts 22 and the purge gas may be supplied in the remaining plasma generation part 22.

At the next rotation after the modifying process is completed, similar to the second rotation and the fourth rotation, the first gas supply part 16 supplies the purge gas. The supply of the purge gas is performed even in the plasma region ((6) in FIG. 9). Then, the flow comes back to the process (1) to repeat the processes. After repeatedly performing the SiCN film forming processes (1) to (4), the insufficiently-adsorbed carbon atoms are removed by the plasma cure ((5) in FIG. 9). Then, the SiCN film forming processes are repeated again. Thus, the film quality can be increased by leaving the carbon atoms sufficiently adsorbed to the film. By performing the plasma cure, it is possible to strengthen the bonding state of the already-adsorbed carbon atoms within the SiCN film and to improve the film quality. In FIG. 9, the portions indicated by Ex are exhaust portions.

### [One Example of the Flow of a Film Forming Process According to the First Embodiment (in the Case of SiOCN Film (1))]

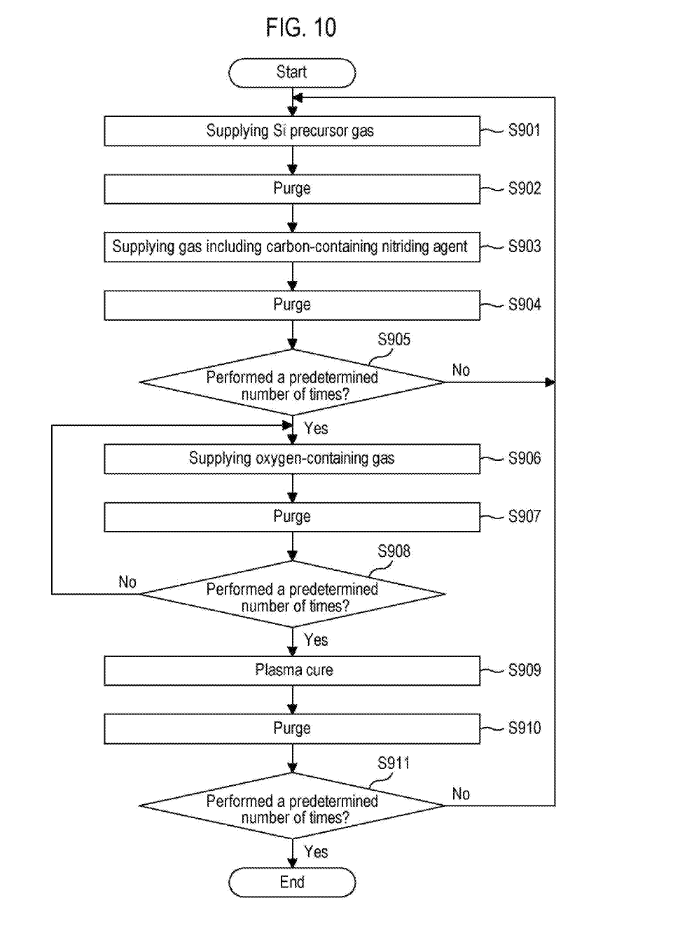

FIG. 10 is a flowchart illustrating a flow of one example of a film forming process of a SiOCN film implemented in the film forming apparatus 10 according to the first embodiment. As illustrated in FIG. 10, in the case of forming a SiOCN film on the substrate W, the substrate W is first mounted in each of the substrate mounting regions 14a and then the operation of the film forming apparatus 10 is started. That is to say, the control of the film forming apparatus 10 using the control part 70 is started. As the mounting table 14 rotates, the substrate W is first moved into the first region R1. At this time, in the first gas supply part 16, the respective valves and the respective flow rate controllers are controlled so that the first precursor gas is supplied to the first region R1. Then, the first precursor gas is supplied by the first gas supply part 16 and is injected toward the substrate W (step S901). The first precursor gas may be, for example, a Si precursor gas such as DCS or the like. By virtue of step S901, a Si film is formed on the substrate W.

After the substrate W has passed through the first region R1, the respective valves and the respective flow rate controllers of the first gas supply part 16 are controlled so that the purge gas is supplied. Then, the first precursor gas remaining in the supply system of the first gas supply part 16 is purged (step S902). If the substrate W is moved into the first region R1 again, the respective valves and the respective flow rate controllers of the first gas supply part 16 are controlled so as to supply the second precursor gas. Then, the first gas supply part 16 supplies the second precursor gas and injects the second precursor gas toward the substrate W (step S903). The second precursor gas may be, for example, a gas including a carbon-containing nitriding agent. By virtue of step S903, a SiCN film is formed on the substrate W.

After the substrate W has passed through the first region R1, the respective valves and the respective flow rate controllers of the first gas supply part 16 are controlled so that the purge gas is supplied. Then, the second precursor gas remaining in the supply system of the first gas supply part 16 is purged (step S904).

Subsequently, the film forming apparatus 10, namely the control part 70, determines whether the processes of steps S901 to S904 have been performed a predetermined number of times (step S905). If the control part 70 determines that the processes of steps S901 to S904 have not been performed a predetermined number of times (if “No” at step S905), the flow comes back to step S901 where the supply of the first precursor gas is performed by the first gas supply part 16. On the other hand, if it is determined that the processes of steps S901 to S904 have been performed a predetermined number of times (if “Yes” at step S905), the control part 70 causes the plasma generation part 22 to supply a third gas to the plasma region, namely the second region R2 (step S906). In the present embodiment, an O₂ gas is supplied as the third gas. By virtue of step S906, a SiOCN film is formed on the substrate W.

With regard to the switching of the gases supplied to the plasma region, for example, the plasma generation part 22 is configured such that the Ar gas is supplied from the gas supply source 62g and the O₂ gas is supplied from the gas supply source 50g. The supply timings of different kinds of gases may be controlled in conformity with the rotation of the mounting table 14. At the next rotation of the mounting table 14, the purge gas is supplied from the plasma generation part 22 to the plasma region to perform a purge operation (step S907).

Subsequently, the control part 70 determines whether the processes of steps S906 and S907 have been performed a predetermined number of times (step S908). If the control part 70 determines that the processes of steps S906 and S907 have not been performed a predetermined number of times (if “No” at step S908), the flow comes back to step S906 to repeat the processes. On the other hand, if it is determined that the processes of steps S906 and S907 have been performed a predetermined number of times (if “Yes” at step S908), the control part 70 causes the plasma generation part 22 to supply the modifying gas, thereby performing a plasma cure (step S909). For example, an Ar gas is supplied as the modifying gas. At the next rotation, the purge gas is supplied to both the first region R1 and the second region R2 (step S910). Then, the control part 70 determines whether the plasma cure has been performed a predetermined number of times (step S911). If it is determined that the plasma cure has not been performed a predetermined number of times (if “No” at step S911), the control part 70 controls the film forming apparatus 10 so as to perform the process of step S901 again. On the other hand, if it is determined that the plasma cure has been performed a predetermined number of times (if “Yes” at step S911), the control part 70 terminates the processes. In this way, a modified SiOCN film is formed on the substrate W.

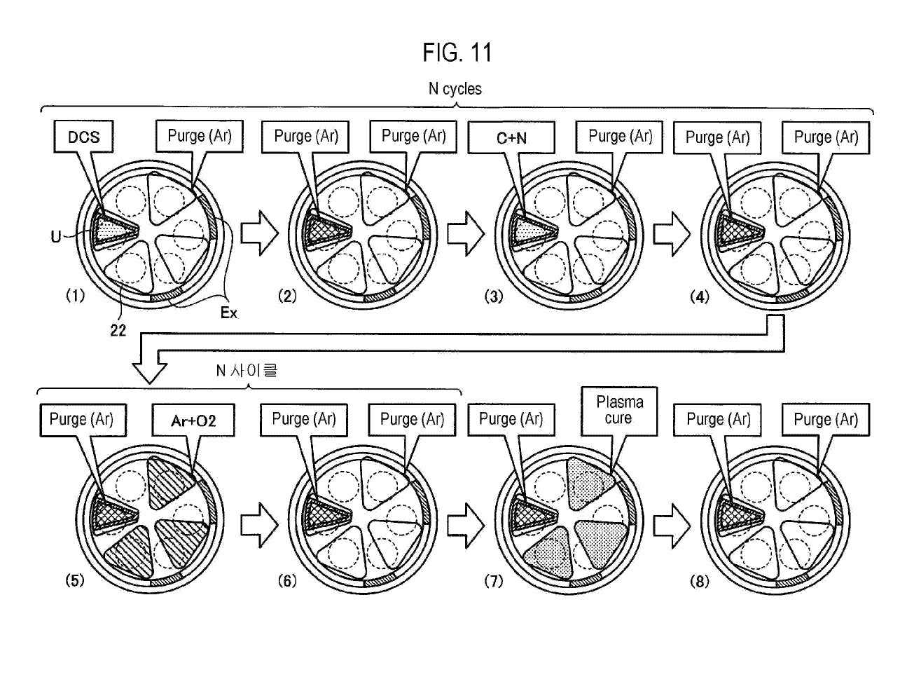

FIG. 11 is a schematic view for explaining the flow of one example of the film forming process of the SiOCN film implemented in the film forming apparatus 10 according to the first embodiment. The processes (1) to (4) illustrated in FIG. 11 are the same as the processes (1) to (4) illustrated in FIG. 9. Furthermore, the process (1) illustrated in FIG. 11 corresponds to the process of step S901 illustrated in FIG. 10. The process (2) illustrated in FIG. 11 corresponds to the process of step S902 illustrated in FIG. 10. The process (3) illustrated in FIG. 11 corresponds to the process of step S903 illustrated in FIG. 10. The process (4) illustrated in FIG. 11 corresponds to the process of step S904 illustrated in FIG. 10. By virtue of the processes (1) to (4) illustrated in FIG. 11, a SiCN film is formed on the substrate W.

In the example illustrated in FIG. 11, the processes (1) to (4) are repeatedly performed N cycles. After the processes (1) to (4) are performed N cycles, as in the process (5) illustrated in FIG. 11, an Ar gas is supplied to the first region R1 to perform a purge operation. Furthermore, an Ar gas and an O₂ gas are supplied to the second region R2 by the plasma generation part 22 so that oxygen atoms are adsorbed to the substrate W. At the next rotation of the mounting table 14, an Ar gas is supplied to the first region R1 and the second region R2 to perform a purge operation ((6) in FIG. 11). Similar to the processes (1) to (4), the processes (5) and (6) illustrated in FIG. 11 are performed N cycles. Furthermore, the processes (5) and (6) illustrated in FIG. 11 correspond to steps S906 and S907 illustrated in FIG. 10.

After the processes (5) and (6) illustrated in FIG. 11 are performed N cycles, a plasma cure is performed in the second region R2 while supplying the Ar gas to the first region R1 to perform a purge operation. That is to say, the Ar gas as the modifying gas is supplied by the plasma generation part 22, thereby generating plasma of the modifying gas and curing the SiOCN film formed on the substrate W ((7) in FIG. 11). At the next rotation of the mounting table 14, the Ar gas is supplied again to both the first region R1 and second region R2 to perform a purge operation ((8) in FIG. 11).

In the example illustrated in FIGS. 10 and 11, the supply of the Si precursor gas and the supply of the gas including the carbon-containing nitriding agent are first performed a predetermined number of times (steps S901 to S904 in FIG. 10 and processes (1) to (4) in FIG. 11). Thus, a SiCN film is formed on the substrate W. Thereafter, the supply of a gas including oxygen is repeated a predetermined number of times (steps S906 and S907 in FIG. 10 and processes (5) and (6) in FIG. 11). Thus, a SiOCN film is formed on the substrate W. Then, a plasma cure is performed to remove the carbon atoms not sufficiently fixed to the interior of the film at this step (steps S909 and S910 in FIG. 10 and processes (7) and (8) in FIG. 11). Then, the flow comes back to the process of supplying the first precursor gas and the second precursor gas (the Si precursor gas and the gas including a carbon-containing nitriding agent), thereby performing the formation process of the SiCN film and the supply process of the oxygen atoms. By repeating the processes while removing the weakly-bonded carbon atoms in this way, it is possible to strengthen the bonds between the atoms included in the film and to improve the film quality.

In the example of the process (5) illustrated in FIG. 11, the Ar gas and the O₂ gas are supplied from all three plasma generation parts 22. However, the present disclosure is not limited thereto. The number of the plasma generation parts 22 that supplies the O₂ gas may be adjusted depending on the amount of O₂ to be adsorbed.

### [One Example of the Flow of a Film Forming Process According to the First Embodiment (in the Case of SiOCN Film (2))]

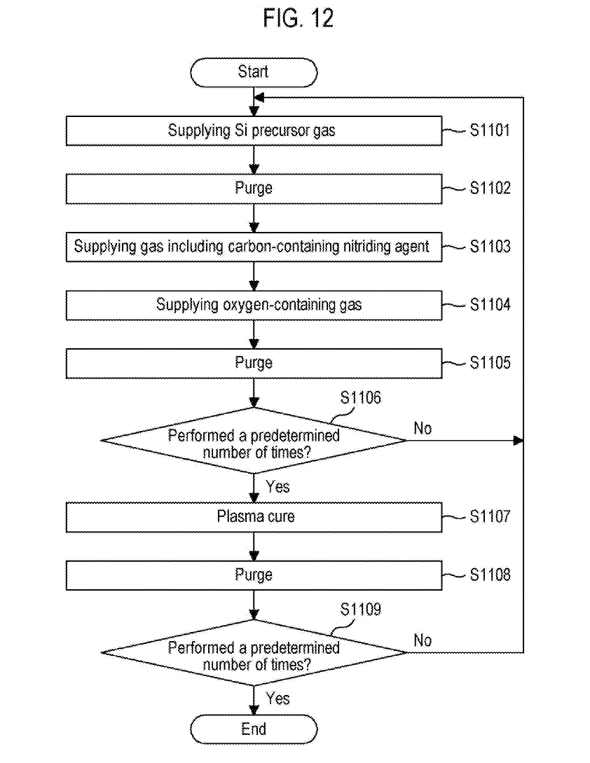

FIG. 12 is a flowchart illustrating a flow of another example of the film forming process of the SiOCN film implemented in the film forming apparatus 10 according to the first embodiment. The processes of steps S1101 to S1104, S1105, S1107 and S1108 illustrated in FIG. 12 are the same as the processes of steps S901 to S903, S906, S907 and S909 to S911 illustrated in FIG. 10. The processes illustrated in FIG. 12 differ from the processes illustrated in FIG. 10 in that the number of times of the formation process of the SiCN film and the number of times of the supply process of the of the oxygen atoms are collectively determined in the processes illustrated in FIG. 12 whereas the number of times of the formation process of the SiCN film and the number of times of the supply process of the of the oxygen atoms are independently determined in the processes illustrated in FIG. 10. In other respects, the processes illustrated in FIG. 12 are the same as the processes illustrated in FIG. 10.

As illustrated in FIG. 12, in the case of forming a SiOCN film on the substrate W, the substrate W is first mounted in each of the substrate mounting regions 14a and then the operation of the film forming apparatus 10 is started. That is to say, the control of the film forming apparatus 10 using the control part 70 is started. As the mounting table 14 rotates, the substrate W is first moved into the first region R1. At this time, in the first gas supply part 16, the respective valves and the respective flow rate controllers are controlled so that the first precursor gas is supplied to the first region R1. Then, the first precursor gas is supplied by the first gas supply part 16 and is injected toward the substrate W (step S1101). The first precursor gas may be, for example, a Si precursor gas such as DCS or the like.

After the substrate W has passed through the first region R1, the respective valves and the respective flow rate controllers of the first gas supply part 16 are controlled so that the purge gas is supplied. Then, the first precursor gas remaining in the supply system of the first gas supply part 16 is purged (step S1102). If the substrate W is moved into the first region R1 again, the respective valves and the respective flow rate controllers of the first gas supply part 16 are controlled so as to supply the second precursor gas. Then, the first gas supply part 16 supplies the second precursor gas and injects the second precursor gas toward the substrate W (step S1103). The second precursor gas may be, for example, a gas including a carbon-containing nitriding agent. Thus, a SiCN film is formed on the substrate W.

During the rotation at which the second precursor gas is supplied, the control part 70 causes the plasma generation part 22 to supply a third gas (an oxygen-containing gas) to the plasma region, namely the second region R2 (step S1104). At the next rotation of the mounting table 14, the first gas supply part 16 is caused to supply the purge gas to the first region R1 and the plasma generation part 22 is caused to supply the purge gas to the plasma region (step S1105).

Subsequently, the control part 70 determines whether the processes of steps S1101 to S1105 have been performed a predetermined number of times (step S1106). If the control part 70 determines that the processes of steps S1101 to S1105 have not been performed a predetermined number of times (if “No” at step S1106), the flow comes back to step S1101 to repeat the processes. On the other hand, if it is determined that the processes of steps S1101 to S1105 have been performed a predetermined number of times (if “Yes” at step S1106), the control part 70 causes the plasma generation part 22 to supply the modifying gas, thereby performing a plasma cure (step S1107). At the next rotation, the purge gas is supplied to both the first region R1 and the second region R2 (step S1108). Then, the control part 70 determines whether the plasma cure has been performed a predetermined number of times (step S1109). If it is determined that the plasma cure has not been performed a predetermined number of times (if “No” at step S1109), the control part 70 controls the film forming apparatus 10 so as to perform the process of step S1101 again. On the other hand, if it is determined that the plasma cure has been performed a predetermined number of times (if “Yes” at step S1109), the control part 70 terminates the processes. In this way, a SiOCN film is formed on the substrate W.

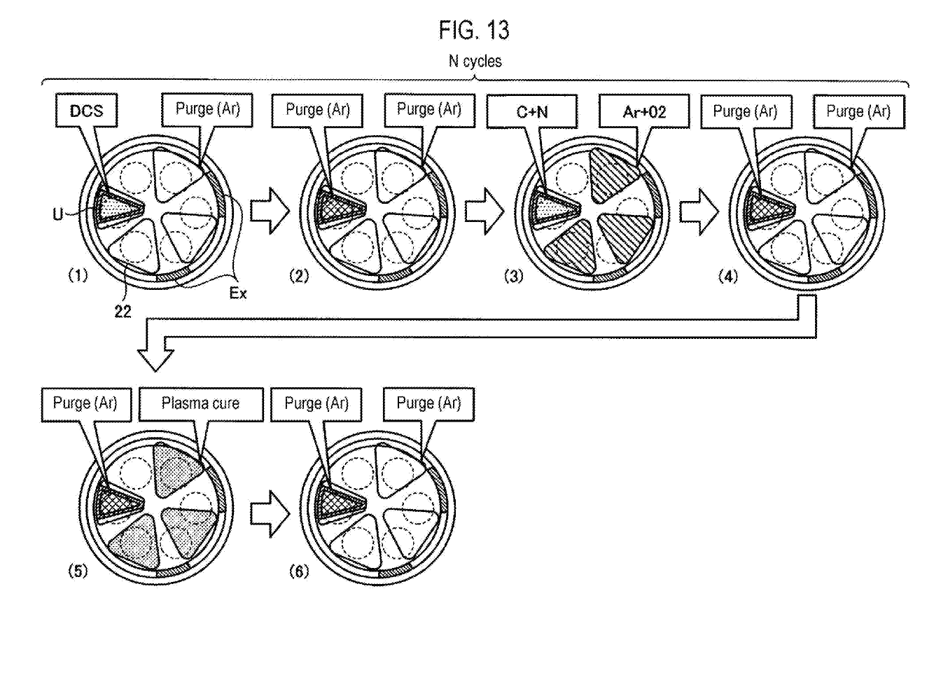

FIG. 13 is a schematic view for explaining the flow of another example of the film forming process of the SiOCN film implemented in the film forming apparatus 10 according to the first embodiment. The processes illustrated in FIG. 13 differ from the processes illustrated in FIG. 11 in that the second precursor gas and the oxygen-containing gas (the third gas) are supplied during the same rotation. The processes (1), (2) and (4) to (6) illustrated in FIG. 13 are the same as the processes (1), (2) and (6) to (8) illustrated in FIG. 11. Hereinafter, descriptions on the same processes as the processes illustrated in FIG. 11 will be omitted.

In the processes illustrated in FIG. 13, the Si precursor gas is supplied and the purge operation is performed by the processes (1) and (2), thereby forming a Si film. At the next rotation, the gas including a carbon-containing nitriding agent is supplied to the first region R1 and the Ar gas and the O₂ gas are supplied to the second region R2 ((3) in FIG. 13). Even at this time, by operating the second gas supply part 20 and the exhaust part 18 disposed in the first region R1, the first region R1 and the second region R2 are separated from each other so that the gas existing in the first region R1 and the gas existing in the second region R2 are not mixed with each other. Then, at the next rotation, the purge gas is supplied to both the first region R1 and the second region R2, thereby removing the residual gas ((4) in FIG. 13).

In the processes illustrated in FIG. 13, the processes (1) to (4) are first performed N cycles, thereby forming a SiOCN film. Thereafter, a plasma cure is performed ((5) in FIG. 13). By virtue of the plasma cure, the atoms not sufficiently adsorbed in the processes (1) to (4) are removed while leaving only the sufficiently-bonded atoms. Thereafter, the first region R1 and the second region R2 are purged with an Ar gas ((6) in FIG. 13). If the number of times of the plasma cure fails to reach a predetermined number of times, the flow comes back to the process (1) to repeat the formation process of the SiOCN film. As described above, even in the processes illustrated in FIG. 13, by repeating the film forming process while removing the weakly-bonded atoms, it is possible to strengthen the bonds between the atoms included in the film and to improve the film quality.

Furthermore, in the first embodiment, the rotation speed of the mounting table 14 when performing the film forming process may be adjusted depending on the process contents. For example, in the film forming process of the SiOCN film illustrated in FIG. 11, the rotation speed of the mounting table 14 may be adjusted so that the processes (1), (2) and (4) to (8) are performed during one rotation of 12 seconds and the process (3) is performed during one rotation of 18 seconds. This makes it possible to reliably perform the process at every rotation and to reliably proceed to the process at the next rotation.

### Effects of the First Embodiment

As described above, the film forming method according to the first embodiment is directed to a film forming method for forming a nitride film on a workpiece substrate accommodated within a process vessel. The film forming method according to the first embodiment includes a first reaction step of supplying a first precursor gas to the workpiece substrate accommodated within the process vessel, a second reaction step of supplying a second precursor gas to the workpiece substrate accommodated within the process vessel, and a modifying step of generating plasma of a modifying gas just above the workpiece substrate by supplying the modifying gas into the process vessel and supplying microwaves from an antenna into the process vessel, and plasma-processing, by the plasma thus generated, a surface of the workpiece substrate subjected to the first and second reaction steps using the first and second precursor gases. In this way, a film is formed by independently injecting two kinds of precursor gases toward the substrate. Thereafter, plasma of the modifying gas is generated. The workpiece is exposed to the plasma thus generated. Thus, among the materials existing within the film thus generated, a weakly-bonded material can be removed while leaving only a strongly-bonded material. This makes it possible to improve the film quality of a nitride film as formed. Furthermore, by modifying the film with the plasma, it is possible to realize modification while suppressing damage to the film. In addition, the probability of adsorption of the respective materials to the substrate and the modification using the plasma can be realized at a desired level by adjusting the process conditions.

Furthermore, in the film forming method according to the first embodiment, the first precursor gas contains silicon and the second precursor gas contains carbon atoms and nitrogen atoms. Thus, a SiCN film can be formed by the film forming method. It is possible to leave strongly-bonded carbon atoms while removing carbon atoms weakly bonded to silicon. Furthermore, by performing the modifying process with the plasma, it is possible to expect the improvement of a bonding state of carbon atoms.

Furthermore, in the film forming method according to the first embodiment, the modifying step is performed once each time when the first reaction step and the second reaction step are repeatedly performed a predetermined number of times. Thus, by additionally performing the first reaction step and the second reaction step using the first and second precursor gases after the weakly-bonded material is removed by the modifying step, it is possible to adjust the amount of the materials contained in the film and to improve the bonding state of the materials within the film. Furthermore, by adjusting the number of repetition times of the first reaction step and the second reaction step and adjusting the number of performing times of the modifying step, it is possible to easily adjust the film quality.

Furthermore, the film forming method according to the first embodiment further includes a third reaction step of supplying a third gas to the workpiece substrate accommodated within the process vessel and a removal step of purging a mechanism for supplying the first precursor gas, the second precursor gas and the third gas, which is performed after the first reaction step, the second reaction step and the third reaction step but before the modifying step. Thus, a material differing from the material for forming a film on the substrate at the first reaction step and the second reaction step can be supplied to the substrate at the third reaction step. Furthermore, the gases used in forming a film at the first reaction step, the second reaction step and the third reaction step are purged before performing the modifying step. This makes it possible to prevent different kinds of gases from being mixed with each other and to prevent the plasma of the modifying gas from being mixed with other gases. It is therefore possible to easily perform a film forming process using plural kinds of gases.

Furthermore, in the film forming method according to the first embodiment, the first precursor gas contains one of monochlorosilane, dichlorosilane, trichlorosilane, tetrachlorosilane and hexachlorodisilane. This makes it possible to form a Si film on the substrate at the first reaction step. In addition, by using, for example, carbon, nitrogen or oxygen as the material for forming a film on the substrate at the second reaction step and the third reaction step, it is possible to form a SiOCN film, a SiCN film or the like.

Furthermore, in the film forming method according to the first embodiment, the second precursor gas is supplied into the process vessel together with ammonia. Thus, for example, in the case where a gas including a carbon-containing nitriding agent is used as the second precursor gas, it is possible to increase the deposition rate while maintaining the deposition temperature at a low temperature. Particularly, even if the internal vapor pressure of the process vessel is low and the gas flow rate is low, it is possible to increase the deposition rate and to enhance the production efficiency. Furthermore, since the deposition is performed by allowing silicon to be adsorbed at the first reaction step and by introducing nitrogen or carbon together with ammonia at the second reaction step, it is possible to prevent different kinds of gases from being mixed with each other and to prevent generation of an undesired reaction.

Furthermore, in the film forming method according to the first embodiment, the second precursor gas is pyrolyzed at a temperature of 200 degrees C. or more and 550 degrees C. or less. This makes it possible to reduce a deposition temperature and to reduce a thermal budget.

Furthermore, in the film forming method according to the first embodiment, the modifying gas may be a mixed gas of NH₃ and H₂. This makes it possible to easily perform the modification of a film using a mechanism of related art for performing a plasma generation process.

Furthermore, the film forming apparatus according to the first embodiment is a semi-batch-type film forming apparatus. Therefore, as compared with a batch-type apparatus in which multiple substrates are simultaneously processed, it is possible to reduce an in-plane or inter-plane variation of the film thickness or the film composition. Furthermore, as compared with a single-substrate-type apparatus in which substrates are processed one by one, the semi-batch-type film forming apparatus can improve the productivity. In addition, since a mechanism for supplying plural kinds of gases is installed in the shower head, it is possible to easily realize ternary deposition while preventing different gases from being unintentionally mixed with each other.

### Second Embodiment

In the first embodiment, the film forming method is realized by the semi-batch-type film forming apparatus including one shower head and three plasma generation parts (antennas). Next, as a second embodiment, a film forming apparatus including two shower heads and two plasma generation parts (antennas) will be described.

In the first embodiment, plural kinds of precursor gases are supplied from one shower head. Mixing of gases is prevented by installing the gas supply/exhaust mechanism. Furthermore, by allowing the plasma generation parts to supply the Ar gas and the O₂ gas, the reaction process using plural kinds of gases and the modifying process using plasma are realized by one shower head and three plasma generation parts.

In contrast, in the second embodiment, two shower heads are installed so that different precursor gases can be supplied from different shower heads. Furthermore, by forming the two shower heads at different sizes, the adsorption/reaction time of the materials included in the respective precursor gases is adjusted. Thus, the size of a space for adsorption or reaction process can be adjusted by adjusting the size of the shower heads depending on the vapor pressure used in processing the respective materials or the time required in adsorption or reaction of the respective materials.

Furthermore, in the second embodiment, structures for supplying a purge gas are provided between the two shower heads and around the two shower heads to prevent the gases supplied from the two shower heads from being mixed with each other. Furthermore, the structures prevent plasma of a modifying gas from entering a region to which gases are supplied from the two shower heads.

[One Example of a Configuration of Film Forming Apparatus 100 according to the Second Embodiment]

A film forming apparatus 100 according to a second embodiment will be described.

The configuration of the film forming apparatus 100 according to the second embodiment is substantially the same as the configuration of the film forming apparatus 10 according to the first embodiment. Hereinafter, descriptions will be made on the points differing from the film forming apparatus 10 according to the first embodiment.

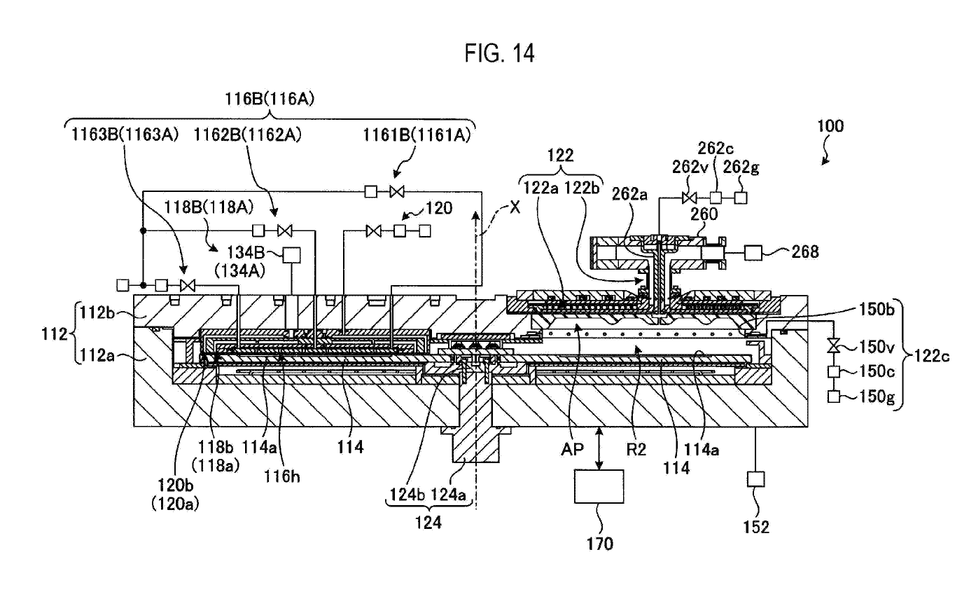

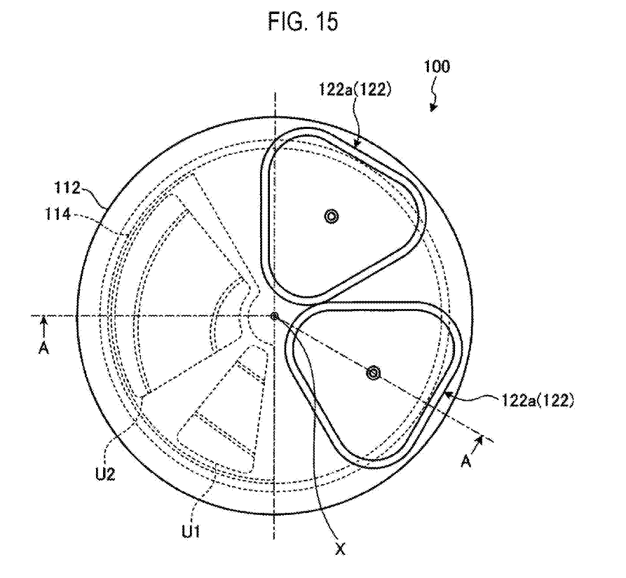

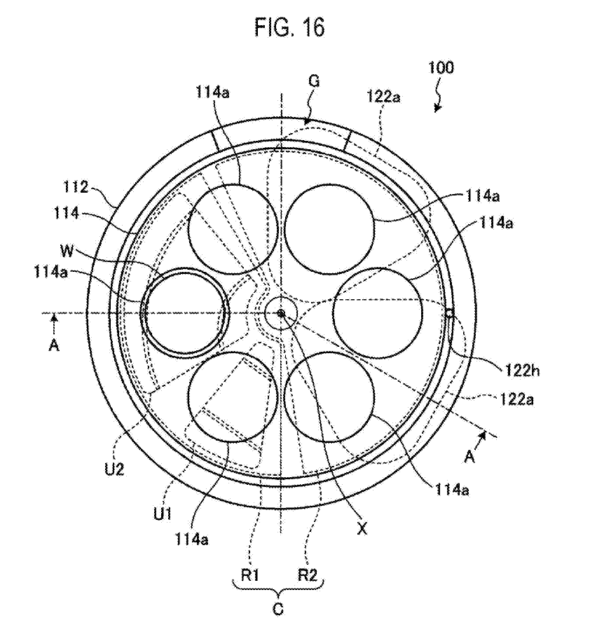

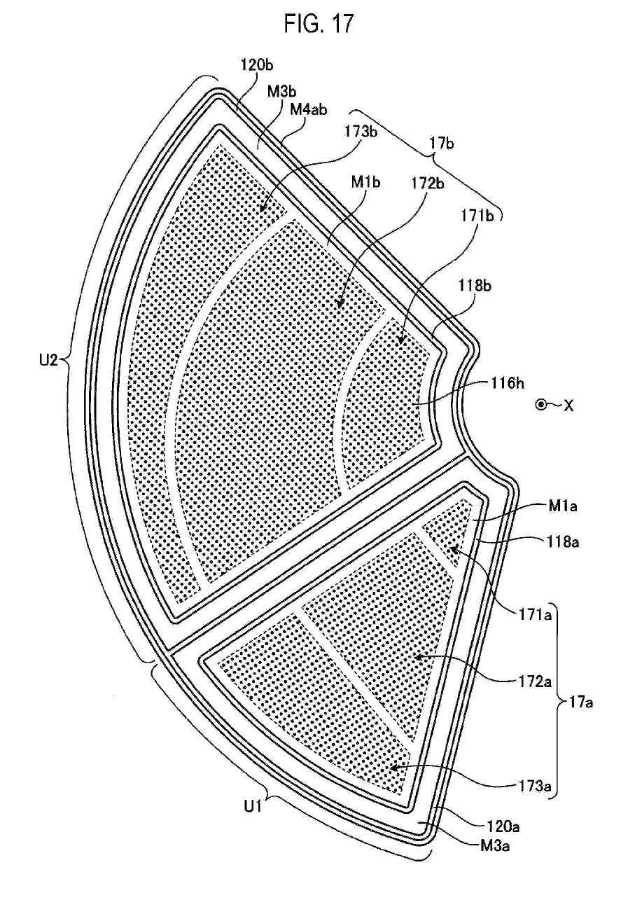

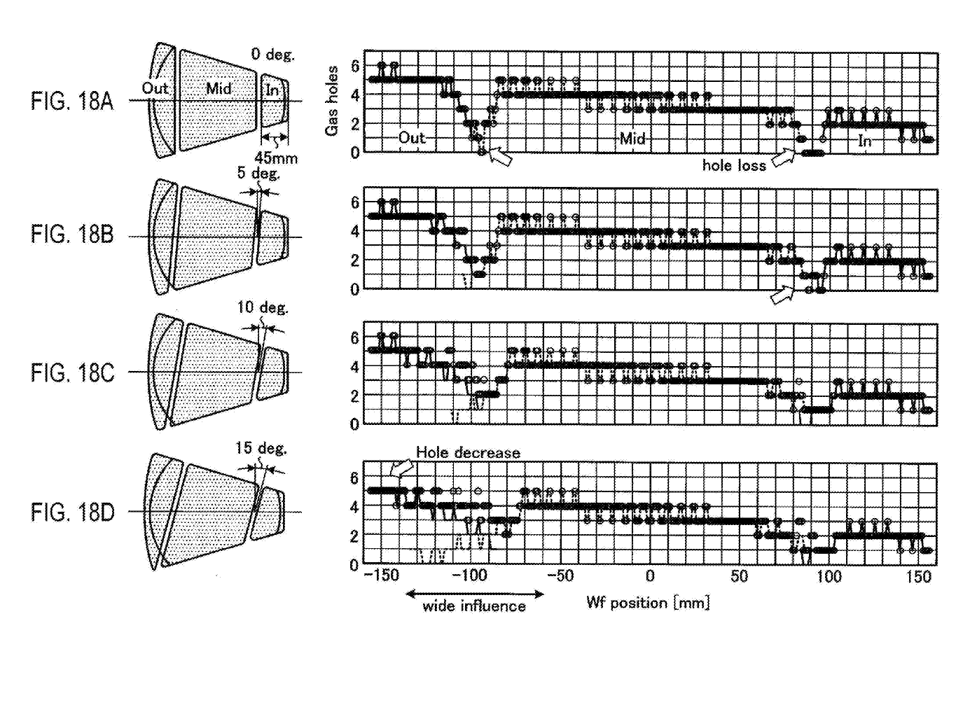

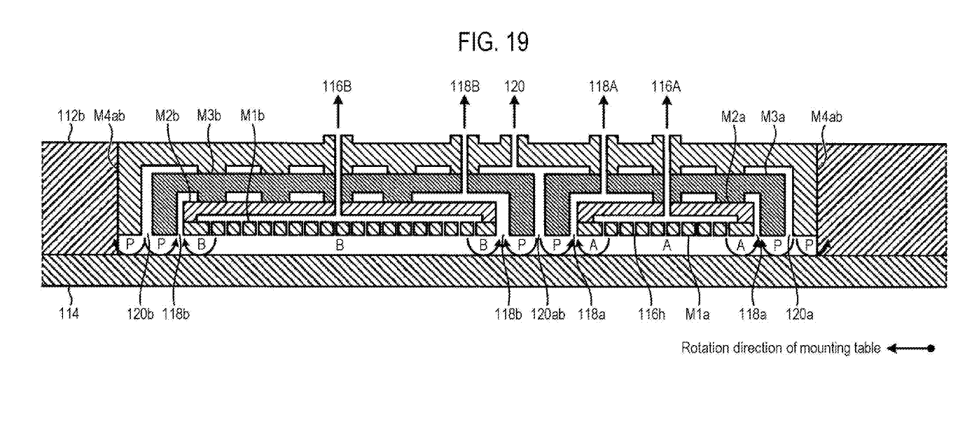

FIG. 14 is a sectional view illustrating one example of the film forming apparatus 100 according to the second embodiment. FIG. 15 is a top view illustrating one example of the film forming apparatus 100 according to the second embodiment. FIG. 16 is a plan view illustrating one example of a state in which a top portion of a process vessel is removed from the film forming apparatus 100 illustrated in FIG. 15. FIG. 14 shows a cross section taken along line A-A in FIGS. 15 and 16. FIG. 17 is a view illustrating one example of an arrangement of injection holes of a shower head provided in the film forming apparatus 100 according to the second embodiment. FIG. 18 is a view for explaining the relationship between the arrangement of the injection holes of the shower head and the quality of films as formed. FIG. 19 is a schematic sectional view illustrating a configuration of two shower heads in the film forming apparatus 100 according to the second embodiment. The film forming apparatus 100 illustrated in FIGS. 14 to 19 includes a process vessel 112 and a mounting table 114. The film forming apparatus 100 further includes first gas supply parts 116A and 116B, exhaust parts 118A and 118B, a second gas supply part 120 and plasma generation parts 122.

As illustrated in FIG. 14, the film forming apparatus 100 is substantially identical in configuration with the film forming apparatus 10. However, as illustrated in FIGS. 15 to 19, the film forming apparatus 100 includes two plasma generation parts 122 (antennas 122a) and two units U1 and U2, namely two shower heads, for supplying precursor gases. Hereinafter, the term “two shower heads” refer to the entire structure formed by the units U1 and U2.

Referring to FIG. 14, the process vessel 112 of the film forming apparatus 100 includes a lower member 112a and an upper member 112b. The film forming apparatus 100 further includes the mounting table 114 disposed within a process chamber C defined by the process vessel 112. The mounting table 114 is rotationally driven about an axis X by a drive mechanism 124. The drive mechanism 124 includes a drive device 124a such as a motor or the like and a rotary shaft 124b. The drive mechanism 124 is installed in the lower member 112a of the process vessel 112.

The unit U1 provided with an injection part 17a (see FIG. 17) and the unit U2 provided with an injection part 17b (see FIG. 17) are installed in the process chamber C defined within the process vessel 112. The units U1 and U2 are one example of shower heads. Details of the units U1 and U2 will be described later.

The film forming apparatus 100 further includes a plurality of plasma generation parts 122 disposed in the process vessel 112. Each of the plasma generation parts 122 includes an antenna 122a disposed above the process vessel 112 and configured to output microwaves. In the example illustrated in FIGS. 14 to 16, the film forming apparatus 100 includes two plasma generation parts 122 and two antennas 122a. However, the number of plasma generation parts 122 and the number of the antennas 122a are not limited to two but may be one or three or more.

As illustrated in FIG. 16, the film forming apparatus 100 includes a mounting table 114 having a plurality of substrate mounting regions 114a formed on the upper surface thereof. The mounting table 114 is a substantially disc-shaped member. The substrate mounting regions 114a for holding substrates W are formed on the upper surface of the mounting table 114 (six substrate mounting regions 114a are formed in the example illustrated in FIG. 16).

As illustrated in FIG. 16, the process chamber C includes a first region R1 and a second region R2 arranged along the circumferential direction about the axis X. The substrates W mounted in the substrate mounting regions 114a sequentially pass through the first region R1 and the second region R2 upon rotation of the mounting table 114. The first region R1 corresponds substantially to a position where the units U1 and U2 are disposed. Furthermore, the second region R2 corresponds substantially to a position where the plasma generation parts 122 are disposed.

The film forming apparatus 100 includes a gate valve G installed in the outer edge of the process vessel 112. Furthermore, the film forming apparatus 100 includes an exhaust port 122h formed under the outer edge of the mounting table 114. An exhaust device 152 is connected to the exhaust port 122h so as to maintain the internal pressure of the process chamber C at a target pressure.

The film forming apparatus 100 includes plasma generation parts 122 installed in apertures AP of the upper member 112b existing above the second region R2 so as to face the upper surface of the mounting table 114. Each of the plasma generation parts 122 includes an antenna 122a and a coaxial waveguide 122b configured to supply microwaves and a modifying gas to the antenna 122a. For example, three apertures AP are formed in the upper member 112b. The film forming apparatus 100 includes, for example, two plasma generation parts 122. The plasma generation parts 122 supplies a modifying gas and microwaves to the second region R2, thereby generating plasma of the modifying gas in the second region R2.

A gas supply source 262g of a modifying gas is connected to the upper end of an inner conductor 262a of the coaxial waveguide 122b via a valve 262v and a flow rate control part 262c such as a mass flow controller or the like. The modifying gas supplied from the valve 262v to the coaxial waveguide 122b is injected to the second region R2. The film forming apparatus 100 further includes a waveguide 260 and a microwave generator 268.

Furthermore, a modifying gas is also supplied from a modifying gas supply part 122c to the second region R2. The modifying gas supply part 122c includes injection parts 150b. For example, the injection parts 150b are installed inside the upper member 112b of the process vessel 112 so as to extend around the apertures AP. The injection parts 150b inject the modifying gas supplied from the gas supply source 150g toward the second region R2. The gas supply source 150g of the modifying gas is connected to the injection parts 150b via a valve 150v and a flow rate control part 150c such as a mass flow controller or the like. The film forming apparatus 100 further includes a control part 170.

Unless specifically mentioned otherwise, the respective components of the film forming apparatus 100 have the same configurations and functions as those of the corresponding components of the film forming apparatus 10 of the first embodiment.

### [One Example of the Configuration of a Shower Head According to the Second Embodiment]

The configuration of the shower head according to the second embodiment will be further described with reference to FIGS. 17 to 19. As illustrated in FIG. 17, the shower head according to the second embodiment includes two shower heads, namely units U1 and U2, which supply gases to the first region R1. All the cross sections of the units U1 and U2 taken along a radial direction passing the axis X of the mounting table 114 have the shape illustrated in FIG. 14. The units U1 and U2 are disposed along the circumferential direction (rotation direction) of the mounting table 114 as illustrated in FIG. 19.

As illustrated in FIG. 19, similar to the unit U of the first embodiment, each of the units U1 and U2 has a structure in which a first member, a second member, a third member and a fourth member are stacked one above another. However, unlike the unit U of the first embodiment, the units U1 and U2 are configured by first members, second members and third members differing from each other and are connected by a common fourth member.

In the unit U1, a second member M2a is disposed on a first member M1a provided with injection holes 116h communicating with a process space through which the substrates W pass. A space into which precursor gases are supplied is formed between the first member M1a and the second member M2a. Furthermore, a third member M3a is disposed on the second member M2a. A space communicating with the process space through which the substrates W pass is formed between the second member M2a and the third member M3a. An exhaust port 118a is formed by the portion in which the space formed between the second member M2a and the third member M3a communicates with the process space. As illustrated in FIG. 14, the exhaust port 118a is connected to an exhaust device 134A such as a vacuum pump or the like.

Similarly, in the unit U2, a second member M2b is disposed on a first member M1b provided with injection holes 116h communicating with a process space through which the substrates W pass. A space into which precursor gases are supplied is formed between the first member M1b and the second member M2b. Furthermore, a third member M3b is disposed on the second member M2b. A space communicating with the process space through which the substrates W pass is formed between the second member M2b and the third member M3b. An exhaust port 118b is formed by the portion in which the space formed between the second member M2b and the third member M3b communicates with the process space. As illustrated in FIG. 14, the exhaust port 118b is connected to an exhaust device 134B such as a vacuum pump or the like.

A fourth member M4ab is disposed so as to cover the third member M3a constituting the unit U1 and the third member M3b constituting the unit U2. The fourth member M4ab is a member common to the units U1 and U2. Spaces into which a purge gas is supplied are formed between the third member M3a and the fourth member M4ab and between the third member M3b and the fourth member M4ab.

Next, flow routes of precursor gases supplied from the units U1 and U2 will be described with reference to FIG. 14. Although the cross-sectional structure of the unit U2 is illustrated in FIG. 14, the cross-sectional structure of the unit U1 is the same as the cross-sectional structure of the unit U2. In FIG. 14, reference symbols of components of the unit U1 are indicated in parentheses in the case where the units U1 and U2 include different corresponding components.

The unit U1 includes the first gas supply part 116A independent from the unit U2. As illustrated in FIG. 14, the first gas supply part 116A includes an inner gas supply part 1161A, a middle gas supply part 1162A and an outer gas supply part 1163A. The inner gas supply part 1161A, the middle gas supply part 1162A and the outer gas supply part 1163A are identical in configuration with the first inner gas supply part 161, the first middle gas supply part 162 and the first outer gas supply part 163 of the first embodiment, respectively. The first gas supply part 116A extends through the fourth member M4ab and the third member M3a and supplies a first precursor gas (indicated by “A” in FIG. 19) from the injection holes 116h into the process space of the first region R1 through a gas flow path communicating with spaces formed between the third member M3a and the second member M2a and between the third member M3a and the first member M1a.

The unit U1 further includes an exhaust part 118A independent from the unit U2. The configuration of the exhaust part 118A is the same as the configuration of the exhaust part 18 of the first embodiment. The exhaust part 118A includes the aforementioned exhaust device 134A. The exhaust part 118A extends through the fourth member M4ab and the third member M3a. The exhaust part 118A exhausts the gas existing within the process space from the exhaust port 118a through a gas flow path communicating with a space formed between the third member M3a and the second member M2a.

The unit U1 further includes the second gas supply part 120 common to the unit U2. The second gas supply part 120 is the same as the second gas supply part 20 of the first embodiment. However, the gas flow paths formed within the units U1 and U2 differ from the gas flow path formed within the unit U of the first embodiment. As illustrated in FIG. 19, the second gas supply part 120 extends through the fourth member M4ab and injects a purge gas (indicated by “P” in FIG. 19) from injection holes 120a, 120b and 120ab into the process space (the first region R1) through gas flow paths formed between the fourth member M4ab and the third member M3a and between the fourth member M4ab and the third member M3b.

The unit U2 includes the first gas supply part 116B independent from the unit U1. As illustrated in FIG. 14, the first gas supply part 116B includes an inner gas supply part 1161B, a middle gas supply part 1162B and an outer gas supply part 1163B. The inner gas supply part 1161B, the middle gas supply part 1162B and the outer gas supply part 1163B are identical in configuration with the first inner gas supply part 161, the first middle gas supply part 162 and the first outer gas supply part 163 of the first embodiment, respectively. The first gas supply part 116B extends through the fourth member M4ab and the third member M3b and supplies a second precursor gas (indicated by “B” in FIG. 19) into the process space of the first region R1 through a gas flow path communicating with spaces formed between the third member M3b and the second member M2b and between the third member M3b and the first member M1b.

The unit U2 further includes the exhaust part 118B independent from the unit U1. The configuration of the exhaust part 118B is the same as the configuration of the exhaust part 18 of the first embodiment. The exhaust part 118B includes the aforementioned exhaust device 134B. The exhaust part 118B extends through the fourth member M4ab and the third member M3b. The exhaust part 118B exhausts the gas existing within the process space from an exhaust port 118b through a gas flow path communicating with a space formed between the third member M3b and the second member M2b.

The unit U2 further includes the second gas supply part 120 common to the unit U1.

As described above, the unit U1 as a supply system for supplying the first precursor gas and the unit U2 as a supply system for supplying the second precursor gas are provided independently of each other, thereby preventing mixing of gases. Furthermore, the exhaust ports 118a and 118b of the exhaust part 118A and the exhaust part 118B are disposed between the space into which the first precursor gas is supplied from the injection hole 116h of the unit U1 and the space into which the second precursor gas is supplied from the injection hole 116h of the unit U2. Thus, the first precursor gas supplied from the unit U1 is exhausted by the exhaust part 118A and the second precursor gas supplied from the unit U2 is exhausted by the exhaust part 118B. Accordingly, the first precursor gas and the second precursor gas are exhausted through different exhaust ports and are prevented from being mixed with each other.

Furthermore, the second gas supply part 120 for supplying the purge gas is installed in common to the units U1 and U2, thereby supplying the purge gas so as to surround the entirety of the units U1 and U2. That is to say, as illustrated in FIG. 19, the purge gas is injected toward the process space from between the fourth member M4ab and the third member M3a and from between the fourth member M4ab and the third member M3b (from the injection holes 120a and 120b). The exhaust ports 118a and 118b are respectively disposed closer to the centers of the respective units than the injection holes 120a and 120b from which the purge gas is injected. Thus, the residual first precursor gas and the residual second precursor gas are exhausted from the exhaust ports 118a and 118b. The purge gas is drawn inward from the outer peripheries of the respective units and is exhausted together with the respective precursor gases.

Thus, it is possible to prevent the first and second precursor gases supplied from the two shower heads from flowing out of the first region R1. Furthermore, it is possible to prevent the plasma generated in the second region R2 from entering the first region R1. Since the purge gas is supplied by installing the second gas supply part 120 common to the units U1 and U2, it is possible to prevent the plasma from entering the space formed between the units U1 and U2.

### [One Example of Arrangement of Injection Holes of Two Shower Heads]

Referring back to FIG. 17, one example of an arrangement of the injection holes of the two shower heads will be further described. The unit U1 includes the injection part 17a and the unit U2 includes the injection part 17b. The injection part 17a includes an inner injection part 171a, a middle injection part 172a and an outer injection part 173a. The injection part 17b includes an inner injection part 171b, a middle injection part 172b and an outer injection part 173b. The injection parts 17a and 17b are substantially identical in configuration with each other. However, as illustrated in FIG. 17, the inner injection part 171a, the middle injection part 172a and the outer injection part 173a are separated from one another by linear partitions (elastic members) (see 161b, 162b and 163b in FIG. 6), whereas the inner injection part 171b, the middle injection part 172b and the outer injection part 173b are separated from one another by curved partitions (elastic members).

First, descriptions will be made on the injection part 17a of the unit U1. Each of the inner injection part 171a, the middle injection part 172a and the outer injection part 173a of the injection part 17a includes a plurality of injection holes 116h (see FIG. 14). In the unit U1, the first precursor gas is injected from the inner injection part 171a, the middle injection part 172a and the outer injection part 173a into the first region R1 through the inner gas supply part 1161A, the middle gas supply part 1162A and the outer gas supply part 1163A. As illustrated in FIG. 19, the first precursor gas supplied from a gas supply source passes through the gas supply path extending through the fourth member M4ab, the third member M3a and the second member M2a and reaches the space formed between the first member M1a and the second member M2a. Then, the first precursor gas is supplied from the space formed between the first member M1a and the second member M2a to the injection holes 116h formed in the first member M1a and is injected toward the first region R1. As illustrated in FIG. 14, the flow spaces of the gas supplied from the inner gas supply part 1161A, the middle gas supply part 1162A and the outer gas supply part 1163A are separated from one another by the elastic member installed between the first member M1a and the second member M2a. Thus, by controlling the flow rate control parts installed in the respective gas supply parts, it is possible to supply the gases at different flow rates from the inner injection part 171a, the middle injection part 172a and the outer injection part 173a.

Subsequently, descriptions will be made on the injection part 17b of the unit U2. Each of the inner injection part 171b, the middle injection part 172b and the outer injection part 173b of the injection part 17b includes a plurality of injection holes 116h (see FIG. 14). In the unit U2, the second precursor gas is injected from the inner injection part 171b, the middle injection part 172b and the outer injection part 173b into the first region R1 through the inner gas supply part 1161B, the middle gas supply part 1162B and the outer gas supply part 1163B. As illustrated in FIG. 19, the second precursor gas supplied from a gas supply source passes through the gas supply path extending through the fourth member M4ab, the third member M3b and the second member M2b and reaches the space formed between the first member M1b and the second member M2b. Then, the second precursor gas is supplied from the space formed between the first member M1b and the second member M2b to the injection holes 116h formed in the first member M1b and is injected toward the first region R1. As illustrated in FIG. 14, the flow spaces of the gas supplied from the inner gas supply part 1161B, the middle gas supply part 1162B and the outer gas supply part 1163B are separated from one another by the elastic member installed between the first member M1b and the second member M2b. Thus, by controlling the flow rate control parts installed in the respective gas supply parts, it is possible to supply the gases at different flow rates from the inner injection part 171b, the middle injection part 172b and the outer injection part 173b.

### [Arrangement Angle and Shape of Elastic Member]

As illustrated in FIG. 17, the inner injection part 171a, the middle injection part 172a and the outer injection part 173a are partitioned by the elastic members having a substantially linear shape. The elastic members are disposed so as to obliquely intersect a straight line extending in the radial direction of the substantially-circular mounting table 114 from the axis X of the film forming apparatus 100. Descriptions will be made on the reason why the longitudinal direction of the elastic members is disposed at an angle inclined with respect to the radial direction of the mounting table 114.

FIGS. 18A to 18D are views for explaining the relationship between the arrangement of the injection holes of the shower head and the quality of a film as formed. At the left side in each of FIGS. 18A to 18D, there is illustrated an example of arrangement of the inner injection part, the middle injection part and the outer injection part. Furthermore, at the right side in each of FIGS. 18A to 18D, there is illustrated the relationship between the number of injection holes (gas holes) passing through the respective radial positions on the substrate W and the respective radial positions on the substrate W in the case where the arrangement of the injection parts illustrated at the left side is employed.

Referring first to FIG. 18A, the elastic members are disposed so that the longitudinal direction of the elastic members intersects the radial direction of the mounting table 114 at a right angle. In the example illustrated in FIG. 18A, the radial length of the inner injection part is about 45 mm, the radial length of the middle injection part is about 200 mm, and radial length of the outer injection part is about 45 mm. In this case, as indicated by arrows in the right graph of FIG. 18A, little injection holes exist in the radial positions where the elastic members are disposed. For that reason, when the substrate W passes under the unit U1, the precursor gas is not sufficiently injected to the radial positions of the substrate W corresponding to the elastic members.

Referring to FIG. 18B, the elastic members are disposed so that the longitudinal direction of the elastic members extends obliquely at about 5 degrees with respect to the direction perpendicular to the radial direction of the mounting table 114. In this case, as compared with the example illustrated in FIG. 18A, the positions on the substrate W, above which the injection holes do not pass, are reduced. However, as indicated by an arrow in FIG. 18B, the position through which the injection holes do not pass still exists.

Referring to FIG. 18C, the elastic members are disposed so that the longitudinal direction of the elastic members extends obliquely at about 10 degrees with respect to the direction perpendicular to the radial direction of the mounting table 114. In this case, the positions on the substrate W, above which the injection holes do not pass, are eliminated. The precursor gas is injected from the injection holes in all the positions on the substrate W.

Referring to FIG. 18D, the elastic members are disposed so that the longitudinal direction of the elastic members extends obliquely at about 15 degrees with respect to the direction perpendicular to the radial direction of the mounting table 114. In this case, the positions on the substrate W, above which the injection holes do not pass, are eliminated. However, the number of injection holes passing above the positions on the substrate W decreases in the radial outermost position (the position indicated by an arrow in FIG. 18D).

As described above, the amount of the precursor gas injected on the substrate W varies depending on the arrangement angle of the elastic members. Thus, the flow rate of the gas injected from each of the inner injection part, the middle injection part and the outer injection part is adjusted and the shape of the injection parts is determined by adjusting the arrangement angle or the shape of the elastic members. In the second embodiment, the injection part 17a of the unit U1 has the shape illustrated in FIG. 18C so that the precursor gas can be injected on the substrate W in all the radial positions.

### [Difference Between Injection Part of Unit U1 and Injection Part of Unit U2]

In the second embodiment, the injection part 17a of the unit U1 and the injection part 17b of the unit U2 are formed with different sizes, and the shapes and arrangement directions of the elastic members within the injection parts 17a and 17b are made to be different from each other.

In the second embodiment, the unit U1 supplies and injects the first precursor gas, and the unit U2 supplies and injects the second precursor gas. Depending on the properties of the gases introduced as the first precursor gas and the second precursor gas, there may be a case where different reaction time periods are required in order to enable the molecules of the precursor gases to be sufficiently adsorbed onto the substrate W. Thus, in order to ensure that the molecules of the precursor gases used in deposition are adsorbed onto the substrate W at a desired amount, the sizes of the units U1 and U2 are adjusted. By doing so, the time period during which the substrate W is exposed to the precursor gases is adjusted.

For example, it is assumed that the first precursor gas supplied from the unit U1 is sufficiently adsorbed onto the substrate W even when the reaction time is short and further that the second precursor gas supplied from the unit U2 is not sufficiently adsorbed onto the substrate W unless the reaction time of the second precursor gas is set longer than the reaction time of the first precursor gas. In this case, the unit U2 is formed to become larger than the unit U1 so that the molecules of the respective precursor gases are sufficiently adsorbed onto the substrate W.

If the elastic members have the same shape in the case where the sizes of the units U1 and U2 are made different as described above, there may be a case where, due to the difference in the rotation angles of the respective units, the number of the injection holes in the respective positions of the substrate W is not necessarily set at a desired number. For example, if the elastic members are formed of substantially linear members as illustrated in FIGS. 18A to 18D, even when the injection part is configured as in the left diagram of FIG. 18A, the number of injection holes deviates from the right graph of FIG. 18A as the rotation angle of the unit grows larger. In view of this point, in the second embodiment, the elastic members of the unit U2, which is a larger one of the two units, are formed in a curved shape as illustrated in FIG. 17.

The shape of the elastic members of the units U1 and U2 is not necessarily limited to the shape illustrated in FIG. 17. For example, the size of the units U1 and U2 may be changed depending on the properties of the precursor gases used. For example, the unit U2 may be formed at a size five times or six times larger than the size of the unit U1. For example, the unit U2 may be formed in a semicircular shape. In this case, the number of the plasma generation part (antenna) may be one.

### [One Example of the Flow of a Film Forming Process According to the Second Embodiment (in the Case of SiCN Film)]

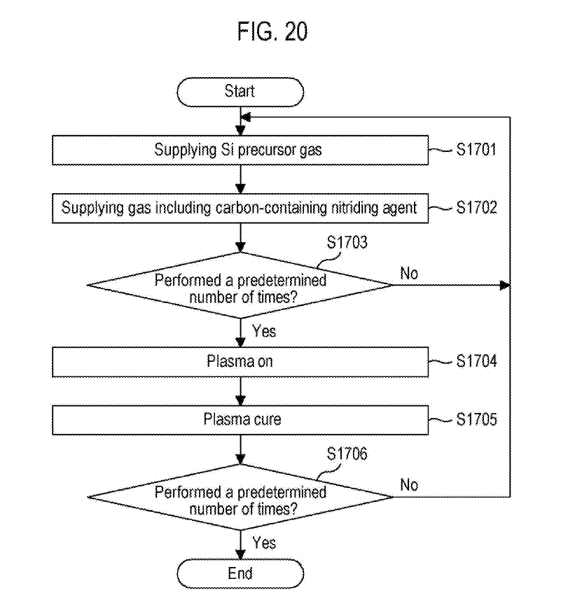

FIG. 20 is a flowchart illustrating one example of a film forming process of a SiCN film implemented in the film forming apparatus 100 according to the second embodiment. As illustrated in FIG. 20, in the case of forming a SiCN film on the substrate W, the substrate W is first mounted in each of the substrate mounting regions 114a and then the operation of the film forming apparatus 100 is started. The control of the film forming apparatus 100 using the control part 170 is started. As the mounting table 114 rotates, the substrate W is moved into the first region R1. The first gas supply part 116A of the unit U1 supplies the first precursor gas to the first region R1 (step S1701). The first precursor gas may be, for example, a Si precursor gas such as DCS or the like. Thus, a Si film is formed on the substrate W.

Subsequently, the substrate W passes under the unit U1 and passes through a region between the units U1 and U2. At this time, the purge gas is injected from the second gas supply part 120 onto the substrate W. The purge gas thus injected is drawn and exhausted by the exhaust port 118a of the exhaust part 118A of the unit U1 and the exhaust port 118b of the exhaust part 118B of the unit U2. Then, the substrate W passes under the unit U2. At this time, the first gas supply part 116B of the unit U2 supplies the second precursor gas to the first region R1 (step S1702). The second precursor gas may be, for example, a gas including a carbon-containing nitriding agent. Thus, a SiCN film is formed on the substrate W. As described in the first embodiment, a gas including a 1H-1,2,3-triazole may be used as the second precursor gas.

Then, the control part 170 of the film forming apparatus 100 determines whether steps S1701 and S1702 have been performed a predetermined number of times (step S1703). If it is determined that the steps S1701 and S1702 have not been performed a predetermined number of times (if “No” at step S1703), the control part 170 continues to rotate the mounting table 114 so that the substrate W passes through the second region R2 and comes back to the first region R1, thereby repeating steps S1701 and S1702.

On the other hand, if it is determined that the steps S1701 and S1702 have been performed a predetermined number of times (if “Yes” at step S1703), the control part 170 causes the plasma generation part 122 to perform a plasma supply process in the second region R2 through which the substrate W passes. First, the control part 170 controls the plasma generation part 122 so as to supply a modifying gas and microwaves (“plasma-on” at step S1704). Then, plasma of the modifying gas is generated by the plasma generation part 122 and is radiated into the second region R2. The substrate W passing through the second region R2 is exposed to the plasma of the modifying gas, whereby a plasma cure is performed (step S1705). After the substrate W passes through the second region R2, the control part 170 determines whether the processes of steps S1704 and S1705 have been performed a predetermined number of times (step S1706). If it is determined that the processes of steps S1704 and S1705 have not been performed a predetermined number of times (if “No” at step S1706), the control part 170 rotates the mounting table 114 and returns the substrate W to the first region R1. Thus, the flow comes back to the process of step S1701. On the other hand, if it is determined that the processes of steps S1704 and S1705 have been performed a predetermined number of times (if “Yes” at step S1706), the control part 170 terminates the processes. Thus, a modified SiCN film is formed on the substrate W.

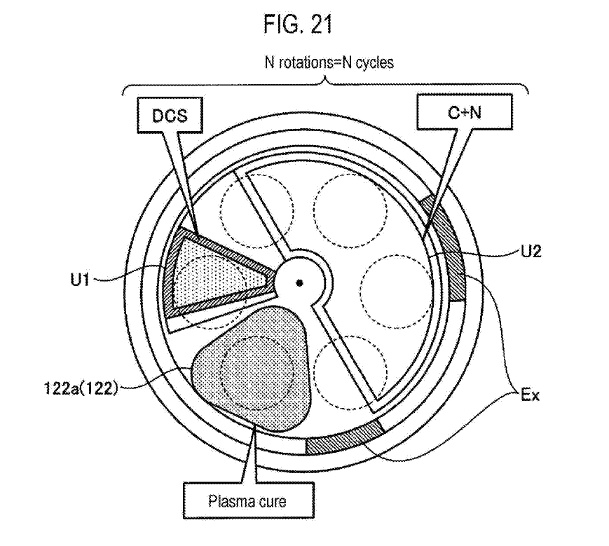

FIG. 21 is a schematic view for explaining the flow of one example of the film forming process of the SiCN film implemented in the film forming apparatus 100 according to the second embodiment. In the example illustrated in FIG. 21, the unit U1 of the film forming apparatus 100 is formed at such a size as to occupy a region having a rotation angle of about 30 degrees, and the unit U2 is formed at such a size as to occupy a region having a rotation angle of about 180 degrees. DCS is used as the first precursor gas. A gas including a carbon-containing nitriding agent and ammonia are used as the second precursor gas. Furthermore, the film forming apparatus 100 includes one plasma generation part 122.

In this film forming apparatus 100, the substrate W is first moved into the first region R1 along with the rotation of the mounting table 114. Then, DCS is injected toward the substrate W by the first gas supply part 116A of the unit U1 disposed above the first region R1 (corresponding to step S1701 in FIG. 20). Thus, a Si film is formed on the substrate W.

Then, the substrate W is moved to under the unit U2. The first gas supply part 116B of the unit U2 injects a mixed gas of a gas including a carbon-containing nitriding agent and ammonia toward the substrate W (corresponding to step S1702 in FIG. 20). Thus, a SiCN film is formed on the substrate W. If the substrate W has not passed through the first region R1 a predetermined number of times (if “No” at step S1703 in FIG. 20), the control part 170 rotates the mounting table 114 so that the substrate W passes through the second region R2. At this time, the plasma generation part 122 does not perform the supply of plasma of the modifying gas. Then, the control part 170 allows the substrate W to come back to the first region R1. Thereafter, the control part 170 causes the unit U1 to supply DCS and causes the unit U2 to supply a gas including a carbon-containing nitriding agent and ammonia, thereby continuously performing the formation of the SiCN film. On the other hand, if the formation on the substrate W of the SiCN film in the first region R1 has been performed a predetermined number of times (if “Yes” at step S1703 in FIG. 20), the control part 170 causes the plasma generation part 122 to start generation of plasma of the modifying gas at the timing at which the substrate W is moved into the second region R2 (step S1704 in FIG. 20). Then, the plasma generation part 122 has the substrate W exposed to the plasma of the modifying gas, thereby performing modification (plasma cure) of the SiCN film formed on the substrate W over a predetermined number of times (step S1705 in FIG. 20). If the plasma cure is performed a predetermined number of times with respect to one substrate W, the process is completed. In the example illustrated in FIG. 21, for example, the mounting table 114 is rotated N times so that the processes of steps S1701 to S1705 are performed N cycles.

Furthermore, while supplying the first precursor gas and the second precursor gas, the supply of the purge gas from the second gas supply part 120 and the exhaust using the exhaust parts 118A and 118B are continuously performed.

As described above, in the film forming method of the SiCN film according to the second embodiment, it is possible to perform three processes, namely the deposition using the first precursor gas, the deposition using the second precursor gas and the plasma cure, by rotating the mounting table 114 once. Furthermore, the process of performing the plasma cure after the deposition using the first and second precursor gases is performed a predetermined number of times and then repeating the deposition using the first precursor gas and the deposition using the second precursor gas, can be easily performed by the on/off control of the plasma generation part 122. Furthermore, by the supply of the purge gas using the second gas supply part 120 and the exhaust using the exhaust parts 118A and 118B, it is possible to prevent the plasma of the modifying gas from moving into a region between the units U1 and U2. Similarly, it is possible to prevent the first precursor gas and the second precursor gas from being mixed with each other. Furthermore, the reaction time of the precursor gases can be adjusted by adjusting the sizes of the units U1 and U2. This makes it possible to realize deposition using the molecules or atoms included in the precursor gases at a desired amount. In addition, by setting the performing frequency of the plasma cure in association with the number of times of formation of the SiCN film, it is possible to adjust the amount of molecules or atoms removed by the plasma cure.

### [One Example of the Flow of a Film Forming Process According to the Second Embodiment (in the Case of SiOCN Film)]

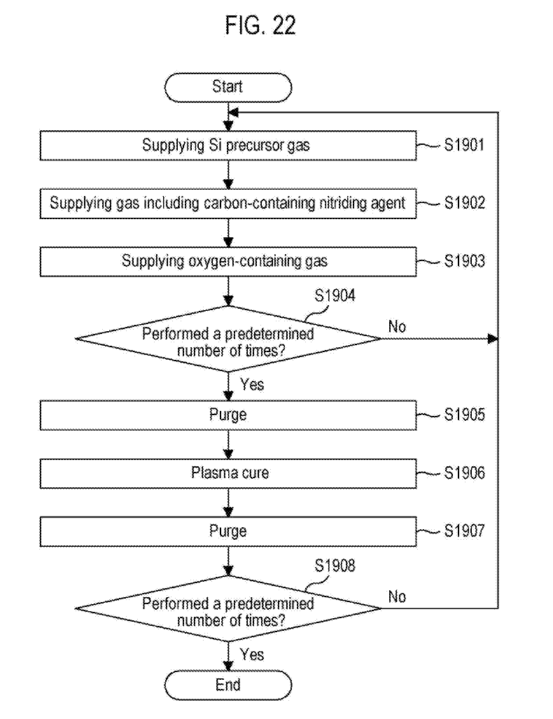

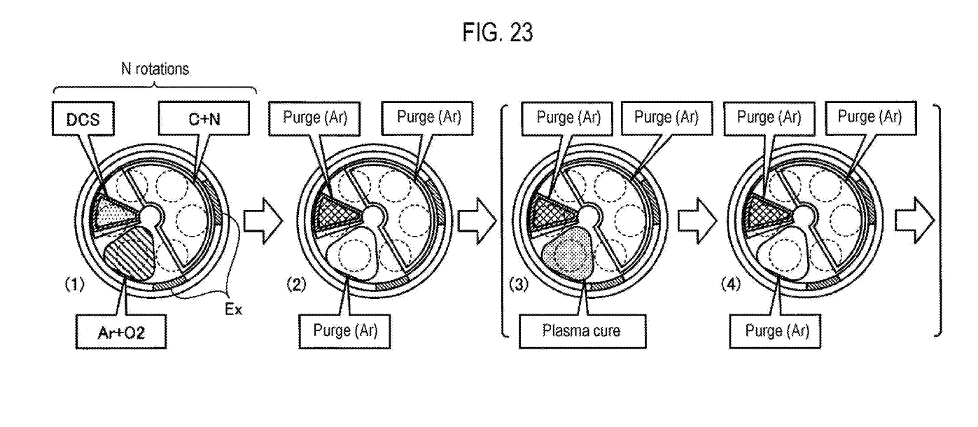

FIG. 22 is a flowchart illustrating one example of a film forming process of a SiOCN film implemented in the film forming apparatus 100 according to the second embodiment. FIG. 23 is a schematic view for explaining the flow of one example of the film forming process of the SiOCN film implemented in the film forming apparatus 100 according to the second embodiment.

As illustrated in FIG. 22, in the case of forming a SiOCN film on the substrate W, the substrate W is first mounted in each of the substrate mounting regions 114a and then the operation of the film forming apparatus 100 is started. That is to say, the control of the film forming apparatus 100 using the control part 170 is started. As the mounting table 114 makes rotation, the substrate W is moved into the first region R1. At this time, in the first gas supply part 116A of the unit U1, the respective valves and the respective flow rate controllers are controlled so that the first precursor gas is supplied to the first region R1. Then, the first precursor gas is supplied by the first gas supply part 116A and is injected toward the substrate W (step S1901). The first precursor gas may be, for example, a Si precursor gas such as DCS or the like. Thus, a Si film is formed on the substrate W.

The substrate W passes under the unit U1 and enters a region between the units U1 and U2. At this time, the purge gas is supplied from the second gas supply part 120 and is injected onto the substrate W. Furthermore, the first precursor gas and the second precursor gas are exhausted by the exhaust parts 118A and 118B, respectively. The purge gas is also exhausted. Thus, the excessive molecules or atoms adhering to the substrate W are removed. In addition, the plasma or the like is prevented from moving into a region between the units U1 and U2.

Subsequently, the substrate W passes under the unit U2. At this time, in the first gas supply part 116B of the unit U2, the respective valves and the respective flow rate controllers are controlled so that the second precursor gas is supplied to the first region R1. Then, the second precursor gas is supplied by the first gas supply part 116B and is injected toward the substrate W (step S1902). The second precursor gas may be, for example, a mixed gas of a gas including a carbon-containing nitriding agent and ammonia. Thus, a SiCN film is formed on the substrate W.

Thereafter, the substrate W passes through the first region R1 and then enters the second region R2. At this time, the plasma generation part 122 is controlled so as to supply a third gas without supplying microwaves. The term “third gas” refers to an oxygen-containing gas such as, for example, a mixed gas of an Ar gas and an O₂ gas. Then, the oxygen-containing gas is injected toward the substrate W by the plasma generation part 122 (step S1903). Thus, a SiOCN film is formed on the substrate W.

After the substrate W passes through the second region R2, the control part 170 determines whether the processes of steps S1901 to S1903 have been performed a predetermined number of times (step S1904). If it is determined that the processes of steps S1901 to S1903 have not been performed a predetermined number of times (if “No” at step S1904), the control part 170 further rotates the mounting table 114 and sends the substrate W to the first region R1 again, thereby repeating the processes from step S1901. On the other hand, if it is determined that the processes of steps S1901 to S1903 have been performed a predetermined number of times (if “Yes” at step S1904), the control part 170 causes the unit U1, the unit U2 and the plasma generation part 122 to supply the purge gas, thereby performing a purge operation (step S1905). For example, an Ar gas may be used as the purge gas.

Subsequently, at the timing at which the substrate W enters the second region R2, the plasma generation part 122 is caused to generate plasma of a modifying gas, thereby performing a plasma cure (step S1906). The plasma cure is performed by, for example, using an Ar gas as the modifying gas. Alternatively, N₂, H₂, NH₃, He or a mixed gas thereof may be used as the modifying gas.

Then, the unit U1, the unit U2 and the plasma generation part 122 supply the purge gas to perform a purge operation (step S1907).

Then, the control part 170 determines whether the plasma cure has been performed a predetermined number of times (step S1908). If it is determined that the plasma cure has not been performed a predetermined number of times (if “No” at step S1908), the control part 170 sends the substrate W to the first region R1 again, thereby repeating the processes from step S1901. If it is determined that the plasma cure has been performed a predetermined number of times (if “Yes” at step S1908), the control part 170 terminates the processes.

The film forming process of the SiOCN film will be further described with reference to FIG. 23. In the process illustrated in FIG. 23, DCS is used as the first precursor gas, and a mixed gas of a gas including a carbon-containing nitriding agent and ammonia is used as the second precursor gas. If the process is started as illustrated in (1) in FIG. 23, the supply of DCS, the supply of a mixed gas of a gas (C+N) including a carbon-containing nitriding agent and ammonia, and the supply of an oxygen-containing gas (Ar+O₂) are performed at the first rotation. That is to say, a SiOCN film is formed by rotating the mounting table 114 once. Furthermore, if the same process is repeated a predetermined number of times by rotating the mounting table 114, it is possible to produce a SiOCN film having a desired thickness. In the example illustrated in FIG. 23, the SiOCN film is produced by rotating the mounting table 114 N times.

After the process illustrated in (1) in FIG. 23 is performed N times, a purge operation illustrated in (2) in FIG. 23 is performed using the unit U1, the unit U2 and the plasma generation part 122. At the next rotation, the plasma generation part 122 is controlled to generate plasma of a modifying gas, thereby performing a plasma cure ((3) in FIG. 23). Then, at the next rotation, a purge operation is performed using the unit U1, the unit U2 and the plasma generation part 122 ((4) in FIG. 23). Then, the process illustrated in (1) in FIG. 23 is repeated again.

### (Modifications)

In the second embodiment, the Ar gas and the O₂ gas are supplied into the second region R2 using the gas supply mechanism of the plasma generation part 122. The timing at which the Ar gas as the purge gas is independently supplied and the timing at which the O₂ gas is supplied in order to form the SiOCN film on the substrate W are controlled by the control signal transmitted from the control part 170. However, the present disclosure is not limited thereto. The plasma generation part 122 may be configured to include a shower head similar to those of the units U1 and U2 so that the Ar gas and the O₂ gas are supplied from the shower head.

### (Modification—Adjustment of Process Order)

In the aforementioned embodiments, when forming the SiCN film, the first precursor gas (the Si precursor gas) and the second precursor gas (the gas including a carbon-containing nitriding agent or the like) are injected toward the substrate in the named order. Thereafter, the plasma cure is performed. Furthermore, when forming the SiOCN film, the first precursor gas (the Si precursor gas), the second precursor gas (the gas including a carbon-containing nitriding agent or the like) and the third gas (the O₂ gas) are injected toward the substrate in the named order. Thereafter, the plasma cure is performed. However, the present disclosure is not limited to this order. Various kinds of gases may be supplied in other orders.

For example, when forming the SiCN film, the second precursor gas (the gas including a carbon-containing nitriding agent or the like) may be first injected toward the substrate. Thereafter, the first precursor gas (the Si precursor gas) may be injected toward the substrate. After repeating this cycle a predetermined number of times, a plasma cure may be performed. The process is repeated in this order.

Examples of a method of changing a process order may include the following methods.

First, descriptions will be made on a case where the SiCN film is formed using the film forming apparatus 10 according to the first embodiment. For example, in the process procedure illustrated in FIG. 9, at the first rotation of the mounting table ((1) in FIG. 9), the second precursor gas (C+N) is supplied instead of the first precursor gas (DCS). Then, at the second rotation, the purge gas is supplied (similar to (2) in FIG. 9). Then, at the third rotation ((3) in FIG. 9), the first precursor gas (DCS) is supplied. Then, at the fourth rotation, the purge gas is supplied (similar to (4) in FIG. 9). In the case of the film forming apparatus 10 according to the first embodiment, by changing the supply order of the gases supplied from the shower head, it is possible to change the process order.

Similarly, in the case of forming the SiOCN film using the film forming apparatus 10 according to the first embodiment, the film forming apparatus 10 may be controlled so as to change the supply order of the first precursor gas (the Si precursor gas), the second precursor gas (C+N) and the third gas (the O₂ gas). For example, the second precursor gas may be supplied in the process (1) illustrated in FIG. 11 and the first precursor gas may be supplied in the process (3). Furthermore, the film forming apparatus 10 may be controlled so as to change the process order in such a way that the processes (5) and (6) illustrated in FIG. 11 are performed before the processes (1) to (4). For example, various kinds of gases may be supplied in the order of the first precursor gas (the Si precursor gas), the third gas (the O₂ gas) and the second precursor gas (C+N). Furthermore, various kinds of gases may be supplied in the order of the second precursor gas (C+N), the first precursor gas (the Si precursor gas) and the third gas (the O₂ gas). Moreover, various kinds of gases may be supplied in the order of the third gas (the O₂ gas), the second precursor gas (C+N) and the first precursor gas (the Si precursor gas).

In the case of forming the SiCN film using the film forming apparatus 100 according to the second embodiment, the process order may be change in the following manner. Hereinafter, descriptions will be made with reference to FIG. 21.

First, in the case of forming the SiCN film using the film forming apparatus 100 according to the second embodiment, the control part 170 controls the film forming apparatus 100 so as to initially perform the process of supplying the second precursor gas from the unit U2. Then, by rotating the mounting table clockwise in FIG. 21, it is possible to supply the gases in the order of the second precursor gas, the third gas and the first precursor gas. Then, a plasma cure is performed after a predetermined number of rotations (a predetermined number of cycles).

Furthermore, instead of changing the gas supply timings, the rotation direction of the mounting table may be reversed. That is to say, in FIG. 21, the mounting table may be rotated counterclockwise rather than clockwise. Then, the gas supply timings are adjusted so that a desired gas is initially supplied to the substrate W. By doing so, it is possible to supply the gases to the substrate W in the order of the first precursor gas (the Si precursor gas supplied from the unit U1), the third gas (the O₂ gas supplied to the second region R2) and the second precursor gas (C+N supplied from the unit U2). Furthermore, the gases may be supplied to the substrate W in the order of the third gas, the second precursor gas and the first precursor gas. Moreover, the gases may be supplied to the substrate W in the order of the second precursor gas, the first precursor gas and the third gas. A plasma cure is performed after rotating the mounting table a desired number of times.

Furthermore, the positions of the units U1 and U2 of the film forming apparatus 100 may be reversed. That is to say, by interchanging the positions of the units U1 and U2 in FIG. 21, the supply order of the first precursor gas and the second precursor gas when the mounting table is rotated clockwise may be reversed. If the supply timings of various kinds of gases are adjusted after reversing the positions of the units U1 and U2 in this way, it is possible to change the supply order of the first precursor gas, the second precursor gas and the third gas.

### Effects of the Second Embodiment

As described above, the film forming apparatus according to the second embodiment includes: a process vessel divided into a plurality of regions along a circumferential direction in which workpiece substrates are moved about an axis by the rotation of a mounting table configured to hold the workpiece substrates and installed to rotate about the axis so that the workpiece substrates can move around the axis; a first shower head disposed to face the mounting table and configured to supply a first precursor gas to a first region among the plurality of regions of the process vessel; a second shower head disposed to face the mounting table and configured to supply a second precursor gas to a second region adjoining the first region among the plurality of regions of the process vessel; and a plasma generation part disposed to face the mounting table and configured to generate plasma of a modifying gas just above the workpiece substrates by supplying the modifying gas to a third region among the plurality of regions of the process vessel and supplying microwaves from an antenna to the third region. Thus, after a film is formed on the substrate by supplying different gases from the two shower heads, the film quality can be improved by the plasma of the modifying gas. Furthermore, after a film forming process is performed by installing the two shower heads in two adjoining regions among the plurality of regions of the process vessel, a modifying process using the plasma is performed in a region differing from the two regions. Thus, if the substrates are rotated by the rotation of the mounting table, it is possible to continuously perform the film forming process and the modifying process. This makes it possible to realize efficient deposition.

Furthermore, in the aforementioned film forming apparatus, the first shower head may be formed smaller than the second shower head. One of the first and second precursor gases requiring a longer reaction time is supplied from a larger one of the two shower heads. The other precursor gas is supplied from a smaller one of the two shower heads. Thus, the shower heads can be properly used depending on the properties of the precursor gases. It is therefore possible to realize an efficient film forming process.

Furthermore, the aforementioned film forming apparatus further includes a gas supply/exhaust mechanism configured to supply a purge gas between the first and second shower heads and around the first and second shower heads so as to prevent the plasma from moving into a space between the first and second shower heads. This makes it possible to prevent plasma of a modifying gas from entering the first region where the first and second shower heads are disposed.

Furthermore, in the aforementioned film forming apparatus, the first shower head is configured to supply a first precursor gas containing silicon and the second shower head is configured to supply a second precursor gas containing carbon atoms and nitrogen atoms. Thus, by rotating the mounting table while supplying different gases from different shower heads, it is possible to efficiently produce a SiCN film.

Furthermore, in the aforementioned film forming apparatus, the plasma generation part includes a first gas supply part configured to supply an oxygen gas to the third region and a second gas supply part configured to, after the supply of the oxygen gas, supply a purge gas to remove the oxygen gas. For example, an Ar gas is supplied as the purge gas. Thus, a SiOCN film can be formed on the substrate by allowing the plasma generation part to supply the oxygen gas without supplying microwaves. After the SiOCN film is formed, the purge gas is supplied to remove the oxygen gas. This enables the plasma generation part to efficiently perform a plasma cure.

Furthermore, in the aforementioned film forming apparatus, each of the first and second shower heads is divided into a plurality of regions, in which flow rates of an injected gas are independently controlled, radially outward from the axis of the process vessel by linear members or curved members extending along a circumferential direction of the process vessel. An inclination angle of the linear members or the curved members of the first shower head with respect to a radial direction of the process vessel is larger than an inclination angle of the linear members or the curved members of the second shower head with respect to the radial direction of the process vessel. By adjusting the flow rates of the gas supplied from the shower head in conformity with the radial positions of the shower head in this way, it is possible to sufficiently inject the gas toward the substrate in all the radial positions. Furthermore, by changing the arrangement angle of the members partitioning the shower head in conformity with the size of the shower head, it is possible to finely adjust the amount of the injected gas in the respective radial positions.

Furthermore, in the film forming apparatus and the film forming method according to the second embodiment, it is possible to achieve the same effects as those of the first embodiment. For example, in the second embodiment, after the SiOCN film is formed into a predetermined thickness, a plasma cure is performed to remove weakly-bonded carbon atoms and to improve the bonding state of the carbon atoms. Thereafter, a process of producing a SiOCN film is performed again. This makes it possible to improve the bonding state of molecules included in the SiOCN film and to improve the quality of a film as formed.

Furthermore, in the film forming apparatus according to the second embodiment, the first precursor gas is supplied from the first shower head and the second precursor gas is supplied from the second shower head. The plasma generation part supplies a mixed gas of Ar and O₂ and supplies a modifying gas and microwaves for a plasma cure. Thus, by rotating the mounting table once, it is possible to realize the supply of the first precursor gas, the supply of the second precursor gas and the supply of O₂ with respect to the substrate. Furthermore, by converting the gas supplied from the plasma generation part to a modifying gas and supplying microwaves, plasma of the modifying gas is generated. Thus, each time when the production process of the SiOCN film is repeatedly performed a predetermined number of times, a plasma cure can be performed at the next rotation. This makes it possible to easily produce the SiOCN film.

### Example 1

### When a Gas Including a Carbon-Containing Nitriding Agent is Used as a Second Precursor Gas

Hereinafter, as Example 1, descriptions will be made on a SiCN film obtained in the case where the aforementioned film forming process is performed using hexachlorodisilane (HCD) as a first precursor gas and using a gas including 1H-1,2.3-triazole as a second precursor gas. The SiCN film is obtained by, for example, performing steps S701 to S704 illustrated in FIG. 8 or steps S1701 to S1702 illustrated in FIG. 20 a predetermined number of times.

In Example 1, the process conditions used in a process of producing a Si film by supplying the first precursor gas (HCD) are as follows.

HCD flow rate: 100 sccm

Deposition time 0.5 min (per one cycle)

Deposition temperature: 550 degrees C.

Deposition pressure: 133.32 Pa (1 Torr)

Furthermore, the conditions of a process of producing a SiCN film by supplying a second precursor gas (a gas including 1H-1,2,3-triazole as a carbon-containing nitriding agent) are as follows.

Triazole flow rate: 100 sccm

Process time: 0.5 min (per one cycle)

Process temperature: 550 degrees C.

Process pressure: 133.32 Pa (1 Torr)

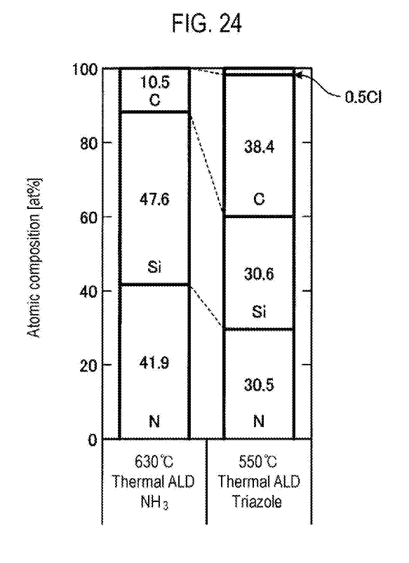

In Example 1, a SiCN film is produced by, for example, performing steps S701 to S704 illustrated in FIG. 8 a predetermined number of times. The atomic composition of the SiCN film thus formed is illustrated in FIG. 24. FIG. 24 is a view illustrating the atomic composition of the SiCN film of Example 1. In FIG. 24, as a reference example, there is illustrated an atomic composition of a SiCN film formed by a thermal atomic layer deposition (ALD) method using a deposition temperature of 630 degrees C., using dichlorosilane (DCS) as a Si precursor gas, using NH₃ as a nitriding agent and using ethylene (C₂H₄) as carbonizing agent.

As illustrated in FIG. 24, the atomic composition of the SiCN film according to the reference example is represented by N=41.9 at %, Si=47.6 at % and C=10.5 at %. According to the reference example, C is added in an amount smaller than the amount of Si or N. According to the reference example, the SiCN film is a Si-rich or N-rich SiCN film.

In contrast, the atomic composition of the SiCN film of Example 1 is represented by N=30.5 at %, Si=30.6 at % and C=38.4 at %. The SiCN film is formed as a C-rich SiCN film in which the amount of C is larger than the amount of Si or N. Furthermore, a small amount of chlorine (Cl) of 0.5 at % is detected from the SiCN film. The chlorine (Cl) originates from HCD which is a Si precursor gas.

As described above, according to the SiCN film of Example 1, as compared with the reference example, it is possible to produce a C-rich SiCN film in which the amount of C is larger than the amount of Si or N. The additional amount of C can be adjusted by adjusting the flow rate of 1H-1,2,3-triazole. That is to say, by performing the process of FIG. 8 or the like using the aforementioned carbon-containing nitriding agent, it is possible to more broadly control the additional amount of C than in the reference example. For example, the additional amount of C affects the chemical resistance of the SiCN film. The broad controllability of the additional amount of C means that it is possible to form a SiCN film whose chemical resistance is higher than that of the reference example.

According to the embodiment, a modifying process is performed with respect to the C-rich SiCN film using plasma, thereby removing easily-desorbed C. Thereafter, the adsorption and nitriding of Si and the addition of C are performed. This makes it possible to improve the quality of the SiCN film while adjusting the addition amount of C.

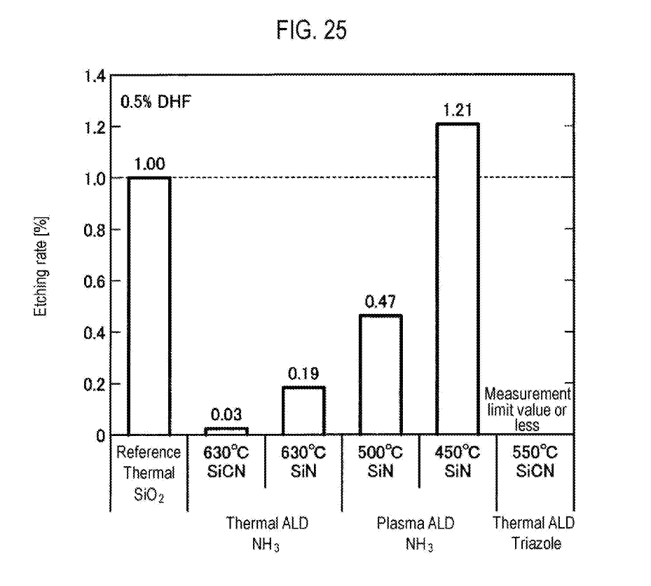

FIG. 25 is a view for explaining an etching rate of the SiCN film of Example 1. In FIG. 25, there are illustrated ratios of etching rates of SiN films and SiCN films when 0.5% DHF is used as an etchant and when an etching rate of a thermal SiO₂ film is used as a reference value of 1.0 (100%).

First, the etching rates of the SiN films will be described.

The etching rate against 0.5% DHF of the SiN film formed by a plasma ALD method using a deposition temperature of 500 degrees C., using DCS as a Si precursor gas and using NH₃ as a nitriding agent is 0.47 (47%) when compared with the reference value and is approximately one half of the etching rate of the thermal SiO₂ film. However, if the deposition temperature is reduced to 450 degrees C., the etching rate against 0.5% DHF is changed to 1.21 (121%) when compared with the reference value and is higher than the etching rate of the thermal SiO₂ film. Thus, it cannot be said that the SiN film formed by the plasma ALD method is superior in chemical resistance, particularly in the resistance against 0.5% DHF.

Furthermore, according to a SiN film formed by a thermal ALD method using a deposition temperature of 630 degrees C., using DCS as a Si precursor gas and using NH₃ as a nitriding agent, the etching rate against 0.5% DHF is 0.19 (19%) when compared with the reference value and can be improved to become about ⅕ of the etching rate of the thermal SiO₂ film. The deposition temperature of the SiN films formed by the thermal ALD method illustrated in FIG. 25 is 630 degrees C. which is higher than the deposition temperature, 450 to 500 degrees C., of the SiN films formed by the plasma ALD method illustrated in FIG. 25. Thus, under a general theory which is not based on the comparison made at the same temperature, it is preferred that the deposition temperature is set high in order to increase the chemical resistance of the SiN films. Furthermore, it may be considered that the thermal ALD method is more advantageous than the plasma ALD method. As is apparent in FIG. 25, the SiN films formed by the thermal ALD method at a high temperature of 630 degrees C. are higher in the resistance against 0.5% DHF than the SiN films formed by the plasma ALD method at a low temperature of 450 to 500 degrees C.

Furthermore, according to a C-added SiCN film formed by a thermal ALD method using a deposition temperature of 630 degrees C., using DCS as a Si precursor gas and using NH₃ as a nitriding agent, the etching rate against 0.5% DHF is 0.03 (3%) when compared with the reference value. That is to say, the SiN film formed by the thermal ALD method is higher in the chemical resistance than the SiN film formed by the plasma ALD method.

According to the SiCN film of Example 1, the etching rate against 0.5% DHF is equal to or lower than a measurement limit value which falls below 0.03 (3%). The result obtained is that the SiCN film of example 1 is hardly etched by 0.5% DHF. Moreover, the deposition temperature of the SiCN film of Example 1 is 550 degrees C. which is lower than 630 degrees C.

As described above, the SiCN film of Example 1 is higher in chemical resistance than the SiCN film formed by the thermal ALD method using DCS as a Si precursor gas and using NH₃ as a nitriding agent.

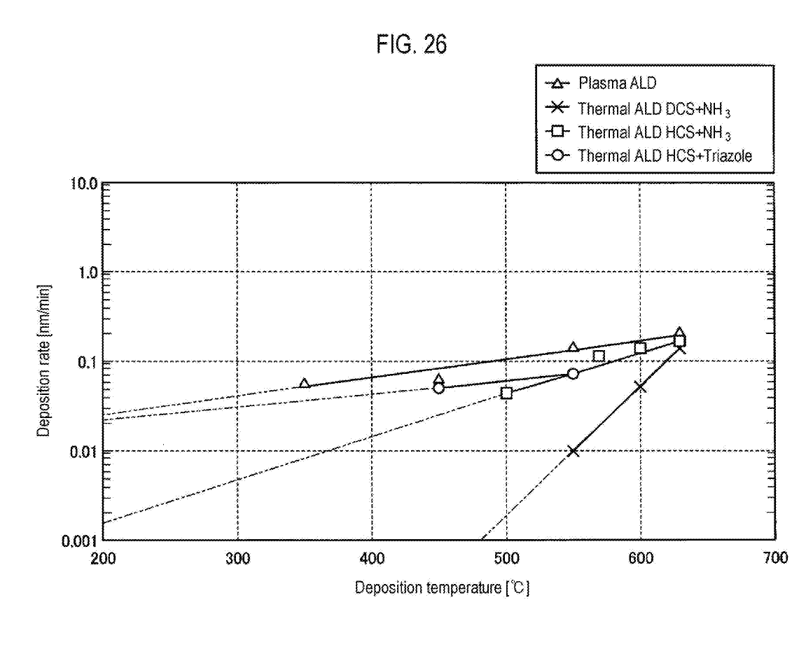

FIG. 26 is a view for explaining the relationship between the deposition temperature of the SiCN film of Example 1 and the deposition rate thereof. As illustrated in FIG. 26, the plasma ALD method using DCS as a Si precursor gas and using NH₃ as a nitriding agent is capable of achieving a deposition rate of 0.02 nm/min or more even under a low deposition temperature and is, therefore, advantageous in low temperature deposition.

Furthermore, the thermal ALD method using DCS as a Si precursor gas and using NH₃ as a nitriding agent is capable of achieving a practical deposition rate of 0.06 to 0.07 nm/min when the deposition temperature is 600 degrees C. However, if the deposition temperature is reduced to 550 degrees C., the deposition rate decreases to about 0.01 nm/min. In the thermal ALD method using DCS as a Si precursor gas and using NH₃ as a nitriding agent, it is hard to form a SiN film if the deposition temperature falls below 500 degrees C. However, if HCD rather than DCS is used as the Si precursor gas, it is possible to ameliorate the reduction of the deposition rate in the low temperature deposition.

According to the SiCN film of Example 1, it is possible to achieve a deposition rate of 0.07 to 0.08 nm/min when the deposition temperature is 550 degrees C. Even if the deposition temperature is reduced to 450 degrees C., it is possible to achieve a deposition rate of 0.05 to 0.06 nm/min Particularly, the deposition rate in a temperature range of 200 degrees C. or more and 550 degrees C. or less is as good as the deposition rate of the plasma ALD method.

As described above, according to the SiCN film of Example 1, even when the deposition is performed under a low temperature, for example, in a temperature range of 200 degrees C. or more and 550 degrees C. or less, without using plasma, it is possible to achieve a deposition rate which is equivalent to the deposition rate achieved in the case of using plasma. One of the reasons is as follows.

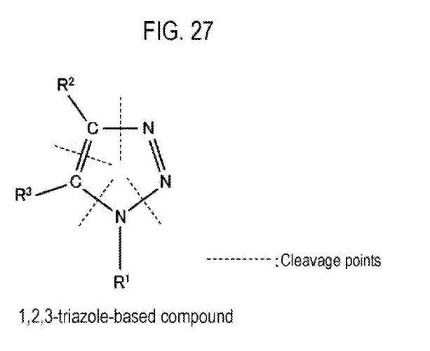

As illustrated in FIG. 27, the 1,2,3-triazole-based compound includes a “N═N—N” bond within a five-member ring. The “N═N” portion in the “N═N—N” bond tends to be decomposed to become nitrogen (N₂, N≡N). Thus, the 1,2,3-triazole-based compound, unlike the usual ring-opening cleavage, has a tendency to undergo cleavage and decomposition at a plurality of points. That is to say, the 1,2,3-triazole-based compound generates “N≡N”. Thus, an electronically unsaturated state occurs within the compound. A decomposition product obtained as a result of cleavage and decomposition of the 1,2,3-triazole-based compound is active. For that reason, even when the deposition temperature is low and falls within a temperature range of, for example, 200 degrees C. or more and 550 degrees C. or less, it is possible to nitride a Si film and, ultimately, to add C.

Thus, even when the deposition temperature is reduced, it is possible to form the SiCN film of Example 1 while maintaining a high deposition rate.

In the case where the gas including a carbon-containing nitriding agent is used, the nitriding and the C adding can be simultaneously performed during the same step using one kind of compound. This is because the 1,2,3-triazole-based compound contains N atoms and C atoms. Thus, a step of carbonizing a Si film or a SiN film becomes unnecessary. This is advantageous in enhancing the throughput.

According to the present disclosure in some embodiments, it is possible to produce a high-performance film while realizing low-temperature deposition.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method for forming a nitride film on a workpiece substrate accommodated within a process vessel, comprising:
performing a first reaction of supplying a first precursor gas to the workpiece substrate accommodated within the process vessel;
performing a second reaction of supplying a second precursor gas to the workpiece substrate accommodated within the process vessel;
performing a modification of generating plasma of a modifying gas just above the workpiece substrate by supplying the modifying gas into the process vessel and supplying microwaves from an antenna into the process vessel, and plasma-processing, by the plasma thus generated, a surface of the workpiece substrate subjected to the first and second reactions using the first and second precursor gases.

2. The method of claim 1, wherein the first precursor gas contains silicon and the second precursor gas contains carbon atoms and nitrogen atoms.

3. The method of claim 1, wherein the modification is performed once each time when the first and second reactions are repeatedly performed a predetermined number of times.

4. The method of claim 1, further comprising:
performing a third reaction of supplying a third gas to the workpiece substrate accommodated within the process vessel; and
performing a removal of purging a mechanism for supplying the first precursor gas, the second precursor gas and the third gas, the removal being performed after the first reaction, the second reaction and the third reaction but before the modification.

5. The method of claim 4, wherein the third gas contains oxygen atoms.

6. The method of claim 1, wherein the first precursor gas contains one of monochlorosilane, dichlorosilane, trichlorosilane, tetrachlorosilane and hexachlorodisilane.

7. The method of claim 1, wherein the second precursor gas is supplied into the process vessel together with ammonia.

8. The method of claim 1, wherein the second precursor gas is pyrolyzed at a temperature of 200 degrees C. or more and 550 degrees C. or less.

9. The method of claim 1, wherein the modifying gas is a mixed gas of NH₃ and H₂.

10. A film forming apparatus, comprising:
a process vessel divided into a plurality of regions along a circumferential direction in which workpiece substrates are moved about an axis by a rotation of a mounting table, the mounting table being configured to hold the workpiece substrates and installed to rotate about the axis so that the workpiece substrates move around the axis;
a first shower head disposed to face the mounting table and configured to supply a first precursor gas to a first region among the plurality of regions of the process vessel;
a second shower head disposed to face the mounting table and configured to supply a second precursor gas to a second region adjoining the first region among the plurality of regions of the process vessel; and
a plasma generation part disposed to face the mounting table and configured to generate plasma of a modifying gas just above the workpiece substrates by supplying the modifying gas to a third region among the plurality of regions of the process vessel and supplying microwaves from an antenna to the third region.

11. The apparatus of claim 10, wherein the first shower head is smaller in size than the second shower head.

12. The apparatus of claim 10, further comprising:
a gas supply/exhaust mechanism configured to supply a purge gas between the first and second shower heads and around the first and second shower heads so as to prevent the plasma from moving into a space between the first and second shower heads.

13. The apparatus of claim 10, wherein the first shower head is configured to supply the first precursor gas containing silicon and the second shower head is configured to supply the second precursor gas containing carbon atoms and nitrogen atoms.

14. The apparatus of claim 10, wherein the plasma generation part includes a first gas supply part configured to supply an oxygen gas to the third region and a second gas supply part configured to, after the supply of the oxygen gas, supply a purge gas to remove the oxygen gas.

15. The apparatus of claim 10, wherein each of the first and second shower heads is divided into a plurality of regions, in which flow rates of an injected gas are independently controlled, radially outward from the axis of the process vessel by linear members or curved members extending along the circumferential direction of the process vessel, and
an inclination angle of the linear members or the curved members of the first shower head with respect to a radial direction of the process vessel is larger than an inclination angle of the linear members or the curved members of the second shower head with respect to the radial direction of the process vessel.
